(19) United States
(12) Patent Application Publication
(10) Pub. No.: US 2007/0202682 A1
(43) Pub. Date: Aug. 30, 2007

(54) MANUFACTURING METHOD OF SEMICONDUCTOR DEVICE

(76) Inventors: Kenichi YAMAMOTO, Tokyo (JP); Toshinori Kawamura, Tokyo (JP); Haruo Akahoshi, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/626,541

(22) Filed: Jan. 24, 2007

(30) Foreign Application Priority Data
Feb. 24, 2006 (JP) 2006-48785

(51) Int. Cl. H01L 21/44

(52) U.S. Cl. 438/612

(57) ABSTRACT

Improvement in shock-resistant strength of a soldered joint is aimed at, and the variation in the plating film formed on an electrode pad is reduced.

In the step which forms a plating film (for example, Ni film) by an electrolytic plating method on the surface of an electrode pad, the first layer is formed in the front surface of the electrode pad with the first current density, and the second layer is formed in the front surface of the first layer with the second current density higher than the first current density after that.

### CROSS-REFERENCE TO RELATED APPLICATION

The present application claims priority from Japanese patent application No. 2006-48785 filed on Feb. 24, 2006, the content of which is hereby incorporated by reference into this application.

### 1. FIELD OF THE INVENTION

The present invention relates to the manufacturing technology of a semiconductor device, and particularly relates to an effective technology in the application to the semiconductor device with which the nickel plating film was formed on the electrode pad.

### 2. DESCRIPTION OF THE BACKGROUND ART

As a semiconductor device, the semiconductor device called a BGA (Ball Grid Array) type, for example is known. A semiconductor chip is mounted in the main surface side of the wiring substrate called an interposer, and this BGA type semiconductor device has package structure by which a plurality of solder bumps of ball state have been arranged as a terminal for external connection at the back surface side of the opposite side of the main surface of a wiring substrate.

In a BGA type semiconductor device, although the thing of various structures is proposed and produced commercially, when it divides roughly, it will be classified into face-up-bonding structure (wire-bonding structure) and face-down-bonding structure. With face-up-bonding structure, electric connection between the electrode pad arranged in the main surface (a circuit formation surface, element formation surface) of a semiconductor chip and the electrode pad (connecting part which includes a part of wiring) arranged in the main surface of a wiring substrate is made by the bonding wire. With face-down-bonding structure, electric connection between the electrode pad arranged in the main surface of a semiconductor chip and the electrode pad arranged in the main surface of a wiring substrate is made by the projection-like electrodes (for example, a solder bump, a stud bump, etc.) which intervened between these electrode pads.

In order that the wiring substrate used for manufacture of a BGA type semiconductor device may aim at improvement in wire bonding property, and a solderability, Ni (nickel)/Au (gold) plating treatment is performed to the electrode pad to which a wire is connected, the electrode pad to which a solder bump is connected, etc. That is, Ni film is formed on the surface of an electrode pad, and Au film is formed in the front surface of Ni film. Generally in this nickel/Au plating treatment, electrolytic plating method which is suitable for mass production is used.

As publicly known literature relevant to the present invention, there is Japanese Unexamined Patent Publication No. 2005-123598 (Patent Reference 1), for example. The technology regarding the bonding strength of the nickel layer on an electrode and lead-free soldering is disclosed by this Patent Reference 1, and the description that “With the electrode structure which forms a nickel layer and a gold layer one by one on the electrode (signal plane) which usually includes copper, if the ratio of the diffraction peak strength of the plane (200) of the nickel layer directly joined to high temperature lead-free soldering exceeds 30/100 of the totals of the diffraction peak strength of a plane (111), a plane (200), a plane (220), and a plane (311), the bonding strength of the solder ball joined to the electrode will increase. As a result, electric connection is firmly maintainable surely over a long period of time to lead-free soldering.” (refer to paragraph number [0010]) is made. The description that “Diffraction peak strength changes according to the formation conditions of a nickel layer, for example, the current density of nickel plating. And when current density is raised, the strength of a plane (200) increases and solder bonding strength rises.” (refer to paragraph number [0009]) is made by the same Patent Reference 1.

[Patent Reference 1] Japanese Unexamined Patent Publication No. 2005-123598

### SUMMARY OF THE INVENTION

In recent years, the bad influence to the environment by Pb (lead) comes to be regarded as questionable, and Pb free-ization is active also in semiconductor products. Although the solder bump of Sn (tin)-Pb eutectic composition with low melt temperature (Sn (63 wt %)-Pb (37 wt %)) is generally used as a terminal for external connection in the BGA type semiconductor device, the solder bump of Pb free composition, for example, the solder bump of Sn—Ag (silver)-Cu (copper) composition, is being used.

However, the solder bump of Pb free composition is hard (mechanical strength is high) as compared with the solder bump of Sn—Pb eutectic composition, and the shock-resistant strength in the soldered joint after mounting a BGA type semiconductor device in a mounting substrate poses a problem.

A BGA type semiconductor device is mounted in a mounting substrate, and is built into various electronic apparatus. In particular, in portable electronic apparatus, such as a cellular phone, since the danger of drop by a user's carelessness is high, the shock-resistant strength from which trouble, such as a crack, does not happen to a soldered joint even if the impact by drop is applied is required.

Also in a BGA type semiconductor device, since a miniaturization and a narrowing of a pitch progress and the area of a soldered joint is becoming small, the improvement in impact strength of a soldered joint is required.

Connection with the electrode pad with which nickel/Au plating treatment was performed, and a solder bump is made by junction with Ni film on an electrode pad, and a solder bump. Then, the present inventor examined the shock-resistant strength in the soldered joint of Ni film formed by the electrolytic plating method on the surface of the electrode pad, and the solder bump of Pb free composition joined to this Ni film.

According to analyses of a present inventor,

### (1): Impurities, Such as Cl (Chlorine) and C (Carbon), are Included in Ni Film Formed by Electrolytic Plating Method on the surface of Electrode Pad, and Shock-Resistant Strength of Soldered Joint Deteriorates under Influence by These Impurities,

### (2): With Current Density (Current Value/Plating Area) when Forming Ni Film, Concentration of Impurity Included in Ni Film Changes, and it Becomes Low with High Current Density, and Becomes High by Low Current Density,

were found.

FIG. 27 and FIG. 28 are the drawings for explaining the valuation method of impact strength, FIG. 29 is a drawing showing the relation between the chlorine (Cl) concentration in Ni film, and a substrate warp (impact strength: ppm), FIG. 30 is a drawing showing the relation between the current density at the time of Ni film formation (A/dm²), and impact strength (ppm), FIG. 31 is a drawing showing the relation between the current density at the time of Ni film formation (A/dm²), and the chlorine (Cl) concentration in Ni film, and FIG. 32 is a drawing showing the relation between the current density at the time of Ni film formation (A/dm²), and the carbon (C) concentration in Ni film.

As shown in FIG. 27 and FIG. 28, the sample which mounted BGA type semiconductor device 1m in the main surface side of mounting substrate 100 was produced, an impact was given to this sample, and the shock-resistant strength of the soldered joint was evaluated. As an evaluation object part of a soldered joint, the soldered joint of the electrode pad of a wiring substrate and solder bump of BGA type semiconductor device 1m was made into the evaluation object part. As a method of giving an impact to a sample, where a sample is put on mounting base 101 of frame shape, from the back surface of the opposite side of the main surface of mounting substrate 100, probe 102 was dropped at the back surface of mounting substrate 100, and it evaluated. The warp generated in mounting substrate 100 by drop of probe 102 was measured in quantification of the impact by strain gage 103 stuck on the main surface side of mounting substrate 100, and was performed to it.

In FIG. 29, FIG. 31, and FIG. 32, the impurity concentration in Ni film (FIG. 29 and FIG. 31 show chlorine concentration, and FIG. 32 shows carbon concentration) expresses with the ratio over Ni film ion number of counts in secondary ion mass spectrometry (SIMS: Secondary Ion Mass Spectrometry). Using Cs⁺ as primary ion, secondary ion mass spectrometry was 14 kV in acceleration voltage, and performed it with the 5×10⁻⁷ Pa degree of vacuum. When measuring area is more than 300 μm, it is carrying out in current 25 nA, beam diameter 60 μm, etching area 200 μm×200 μm, and data acquisition region 70 μm×70 μm. When measuring area is less than 300 μm, it is carrying out in current 5 nA, beam diameter 20 μm, etching area 200 μm×200 μm, and data acquisition region 40 μm×40 μm.

In FIG. 29 and FIG. 30, the data in a drawing is data when fracture occurs in a soldered joint.

In FIG. 30, data (it displays by ♦) when the plating solution used for formation of Ni film is new, and data (it displays by ▪) when the plating solution is dirty with the protective film (solder-resist film) of the wiring substrate are shown.

As shown in FIG. 29, the impact strength of a soldered joint has deteriorated with the increase in the chlorine concentration in Ni film. Between Ni film and the solder bump, the alloy layer (intermetallic compound layer) including these elements is formed, and adherence with an electrode pad and a solder bump is made by the junction by this alloy layer with Ni film and a solder bump. According to the analyses of a present inventor, since 2 alloy layers from which composition differs were formed and fracture (crack) has occurred from the interface of these two alloy layers when the chlorine concentration in Ni film is high, that the impact strength of a soldered joint deteriorates by existence of two alloy layers from which composition differs is presumed. Chlorine in Ni film is presumed to be what is incorporated from a plating solution at the time of Ni film formation. Therefore, when the plating solution is dirty, the chlorine concentration in Ni film will become high. Here, although chlorine was taken up and explained as an example of the impurity included in Ni film, in the plating solution, impurities, such as carbon and sulfur, are also included plentifully. Also in these impurities, the tendency for the impact strength of a soldered joint to fall with the increase in impurity concentration was suited like chlorine.

As shown in FIG. 30, the impact strength of a soldered joint has deteriorated as current density becomes low. As for the impact strength of a soldered joint, the side where the plating solution is dirty with the protective film etc. has deteriorated.

As shown in FIG. 31, the chlorine concentration in Ni film is increasing as current density becomes low. As shown in FIG. 32, the carbon concentration in Ni film is also increasing as current density becomes low. Since the growth rate of Ni film becomes slow as current density becomes low, this presumes that it becomes easy for an impurity to be incorporated into a film.

From these things, it was found that it was effective to form Ni film with high current density for improvement in shock-resistant strength of a soldered joint.

However, as the result that the present inventor examined further,

### (3): When Ni Film is Formed with High Current Density, Variation in Thickness of Ni Film Should Increase,

### (4): When You Fix Plating Time and Ni Film is Formed with High Current Density, Thickness of Ni Film Should Increase,

were found.

FIG. 33 is a drawing showing the relation between the plating time (minute) of Ni film, and the thickness (μm) of Ni film, when the aim value of the thickness of Ni film is fixed to 8 μm and Ni film is formed (plating thickness aim value fixation), FIG. 34 is a drawing showing the relation between the plating time (minute) of Ni film, and current density (A/dm²), when the aim value of the thickness of Ni film is fixed to 8 μm and Ni film is formed (plating thickness aim value fixation), and FIG. 35 is a drawing showing the relation between average current density (A/dm²), and the thickness of Ni film (μm).

The data of FIG. 33 and FIG. 34 shows the thickness variation at the time of fixing the aim value of the thickness of Ni film to 8 μm, and forming Ni film (plating thickness aim value fixation). As clearly from FIG. 33 and FIG. 34, when Ni film is formed with high current density, the variation in the thickness of Ni film will increase.

At above (3), when the variation in the thickness of Ni film increases, we will be anxious about the following problems.

The protective film (solder-resist film) which includes an insulating resin layer is formed in both faces of the back and front of a wiring substrate as a purpose which protects a wiring. The opening for exposing an electrode pad is formed in this protective film. Ni film and Au film on an electrode pad are formed in the opening, so that it may not project from the front surface of a protective film, but when the variation in the thickness of Ni film increases, Au film and Ni film will project them rather than the front surface of the protective film. In manufacture of a semiconductor device, a wiring substrate may be managed in piles. When Au film and Ni film have projected rather than the protective film, in the overlapping wiring substrate of two sheets, a blemish is attached to the protective film of both wiring substrates. In the case of a blemish which has a bad influence on wiring protection, a wiring substrate becomes defective. This becomes a factor which pushes up the manufacturing cost of a semiconductor device.

From these things, to form Ni film with high current density, it is necessary to reduce the variation in the thickness of Ni film.

FIG. 35 is a drawing showing the relation between average current density (A/dm²), and the thickness of Ni film, when the plating time of Ni film is fixed. As clearly from FIG. 35, when plating time is fixed and Ni film is formed with high current density, (4) the thickness of Ni films will increase. Increase of the thickness of Ni film will be anxious about the following problems.

At a plating step, before and after the step which forms Ni film, since various steps, such as a previous cleaning process and a back cleaning process, are included, when productivity is taken into consideration, the plating time of Ni film is fixed in many cases. Although the thickness of Ni film is controllable in current density and plating time, when plating time is fixed and Ni film is formed with high current density, as shown in FIG. 35, the thickness of Ni film will increase. Since Au film and Ni film project rather than the front surface of a protective film when the thickness of Ni film increases, a problem which is the same as the problem resulting from the above-mentioned (3) occurs.

From these things, to form Ni film with high current density, the thickness reduction of Ni film is required.

Then, the present inventor made the present invention paying attention to the thickness of the portion which contributes to a soldering joint of Ni film.

A purpose of the present invention is to offer a technology which can realize improvement in shock-resistant strength of a soldered joint, and can reduce the variation in the thickness of the plating film formed on the surface of an electrode pad.

Another purpose of the present invention is to offer the technology in which improvement in shock-resistant strength of a soldered joint is realized, and which can realize thickness reduction of the plating film formed on the surface of an electrode pad.

The above-described and the other purposes and novel features of the present invention will become apparent from the description herein and accompanying drawings.

Of the inventions disclosed in the present application, typical ones will next be summarized briefly.

The above-mentioned purpose is attained by forming the first layer in the front surface of the electrode pad with the first current density, and forming the second layer in the front surface of the first layer with the second current density higher than the first current density after that at the step which forms a plating film (for example, Ni film) by an electrolytic plating method on the surface of an electrode pad.

Advantages achieved by some of the most typical aspects of the invention disclosed in the present application will be briefly described below.

According to the present invention, the improvement in shock-resistant strength of a soldered joint is realizable, and the variation in the thickness of the plating film formed on the surface of an electrode pad can be reduced.

According to the present invention, the improvement in shock-resistant strength of a soldered joint is realizable, and the thickness reduction of the plating film formed on the surface of an electrode pad is realizable.

### BRIEF DESCRIPTION OF THE DRAWINGS

FIGS. 1A and 1B are drawings (FIG. 1A is a schematic plan view and FIG. 1B is a schematic cross-sectional view which goes along a′-a′ line of FIG. 1A) showing the internal structure of the semiconductor device which is Example 1 of the present invention;

FIG. 2 is the schematic cross-sectional view which expanded a part of FIG. 1B;

FIG. 3 is the schematic cross-sectional view which expanded the portion of the electrode pad for wire connection of FIG. 2;

FIG. 4 is the schematic cross-sectional view which expanded the portion of the electrode pad for bump connection of FIG. 2;

FIG. 5 is a schematic plan view of the multi-wiring substrate used for manufacture of the semiconductor device which is Example 1 of the present invention;

FIG. 6 is a schematic cross-sectional view expanding and showing a part of multi-wiring substrate of FIG. 5;

FIG. 7 is the schematic cross-sectional view which expanded a part of FIG. 6;

FIG. 8 is the schematic cross-sectional view which expanded the electrode pad portion for wire connection of FIG. 7;

FIG. 9 is the schematic cross-sectional view which expanded the electrode pad portion for bump connection of FIG. 7;

FIG. 10 is a flow chart which shows the manufacturing process of the semiconductor device which is Example 1 of the present invention;

FIGS. 11 to 15 are schematic cross-sectional views showing the manufacturing process of the semiconductor device which is Example 1 of the present invention;

FIGS. 16A to 16C are drawings (FIGS. 16A to 16C are schematic cross-sectional views in each step) for explaining the first bump forming step in manufacture of the semiconductor device which is Example 1 of the present invention;

FIGS. 17A and 17B are drawings (FIGS. 17A and 17B are schematic cross-sectional views in each step) for explaining the second bump forming step in manufacture of the semiconductor device which is Example 1 of the present invention;

FIG. 18 is a schematic plan view showing the outline structure of the module (electronic device) incorporating the semiconductor device which is Example 1 of the present invention;

FIG. 19 is a schematic cross-sectional view which goes along b′-b′ line of FIG. 18;

FIG. 20 is the schematic cross-sectional view which expanded a part of FIG. 19;

FIG. 21 is the schematic cross-sectional view which expanded a part of FIG. 20;

FIG. 22 is a schematic plan view showing the outline structure of the cellular phone (portable electronic apparatus) incorporating the module of FIG. 18;

FIG. 23 is a drawing for explaining the electrolytic plating method;

FIG. 24 is a profile which shows the impurity concentration profile in Ni film;

FIG. 25 is a drawing showing the thickness of Ni film when fixing plating time in 30 minutes and forming Ni film on conditions of 1-3;

FIG. 26 is the drawing which made the table conditions 1-3 of FIG. 25;

FIGS. 27 and 28 are drawings for explaining the valuation method of impact strength;

FIG. 29 is a drawing showing the relation between the chlorine (Cl) concentration in Ni film, and a substrate warp (impact strength: ppm);

FIG. 30 is a drawing showing the relation between the current density at the time of Ni film formation (A/dm²), and impact strength (ppm);

FIG. 31 is a drawing showing the relation between the current density at the time of Ni film formation (A/dm²), and the chlorine (Cl) concentration in Ni film;

FIG. 32 is a drawing showing the relation between the current density at the time of Ni film formation (A/dm²), and the carbon (C) concentration in Ni film;

FIG. 33 is a drawing showing the relation between the plating time (minute) of Ni film, and the thickness (μm) of Ni film;

FIG. 34 is a drawing showing the relation between the plating time (minute) of Ni film, and current density (A/dm²);

FIG. 35 is a drawing showing the relation between average current density (A/dm²), and the thickness of Ni film (μm);

FIGS. 36A and 36B are drawings (FIG. 36A is a schematic cross-sectional view showing the whole structure, and FIG. 36B is the schematic cross-sectional view which expanded a part of FIG. 36A) showing the internal structure of the semiconductor device which is Example 2 of the present invention;

FIG. 37 is a schematic cross-sectional view showing the outline structure of the BGA type semiconductor device which is Example 3 of the present invention;

FIG. 38 is the schematic cross-sectional view which expanded a part of FIG. 37;

FIG. 39 is a cross-sectional view showing the outline structure of the semiconductor device which is Example 4 of the present invention;

FIG. 40 is the principal part cross-sectional view which expanded a part of FIG. 39;

FIG. 41 is a schematic cross-sectional view showing the outline structure of the SiP type semiconductor device which is Example 5 of the present invention; and

FIG. 42 is the schematic cross-sectional view which expanded a part of FIG. 41.

### DETAILED DESCRIPTION OF THE PREFERRED EMBODIMENTS

There will now be described an example of this invention with reference to the accompanying drawings. In all the drawings for describing the examples, members of a like function will be identified by like reference numerals and overlapping descriptions will be omitted.

### Example 1

Example 1 explains the example which applied the present invention to the BGA type semiconductor device of wire-bonding structure, and the module (electronic device) incorporating it.

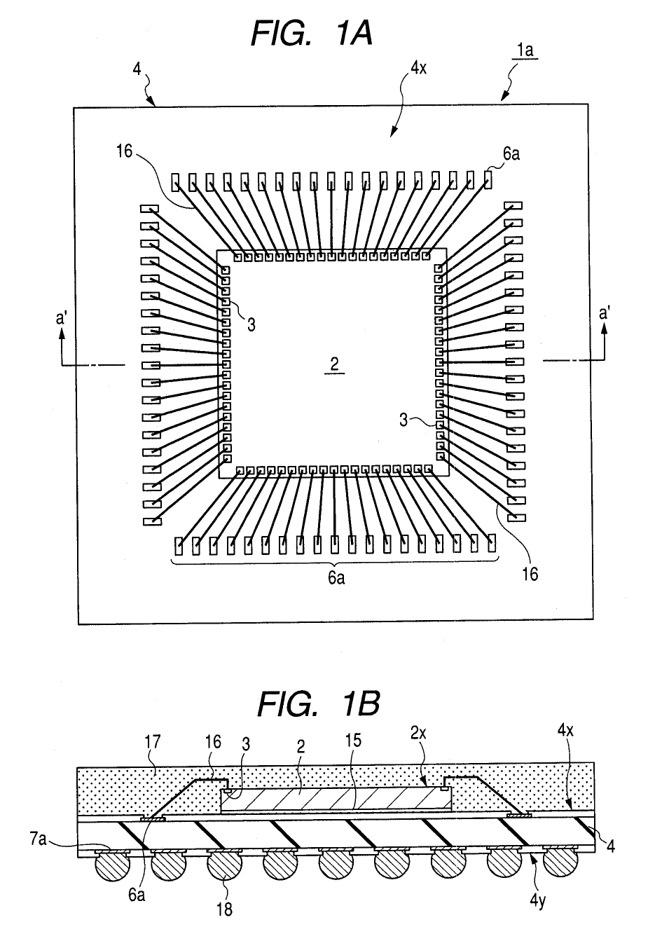

FIG. 1A through FIG. 17B are the drawings concerning the BGA type semiconductor device which is Example 1 of the present invention,

FIGS. 1A and 1B are drawings (FIG. 1A is a schematic plan view and FIG. 1B is a schematic cross-sectional view which goes along a′-a′ line of FIG. 1A) showing the internal structure of a semiconductor device,

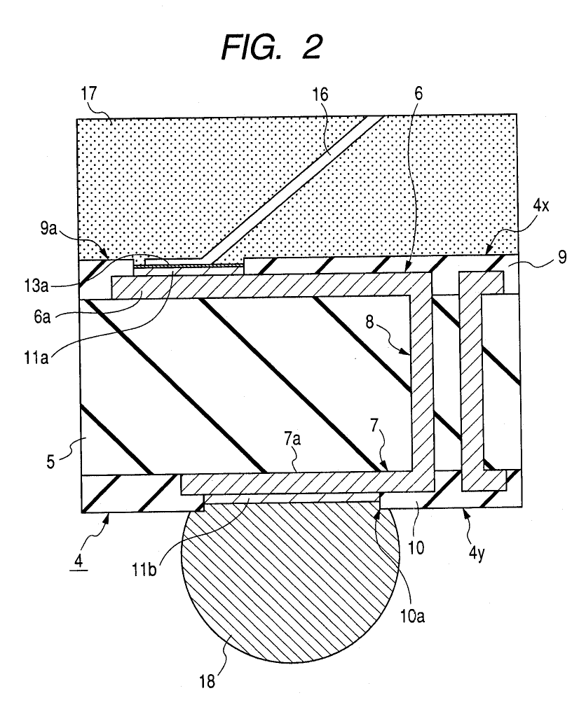

FIG. 2 is the schematic cross-sectional view which expanded a part of FIG. 1B,

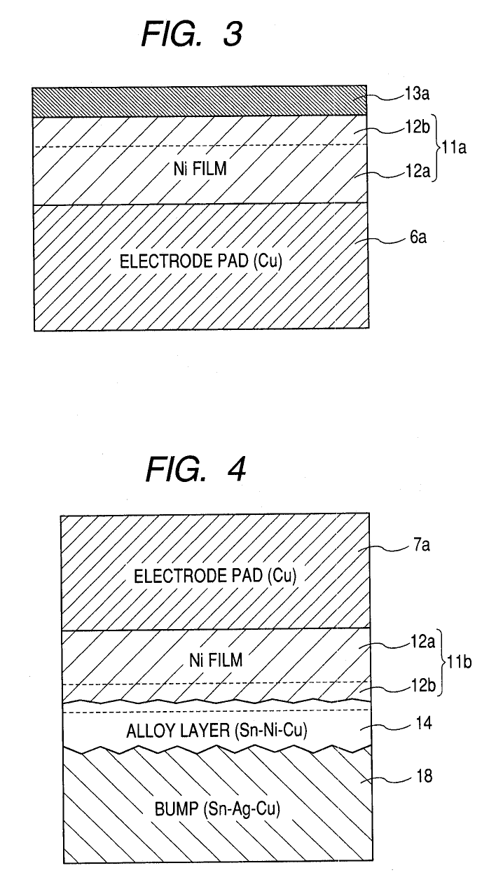

FIG. 3 is the schematic cross-sectional view which expanded a part of FIG. 2 (electrode pad portion for wire connection),

FIG. 4 is the schematic cross-sectional view which expanded a part of FIG. 2 (electrode pad portion for bump connection),

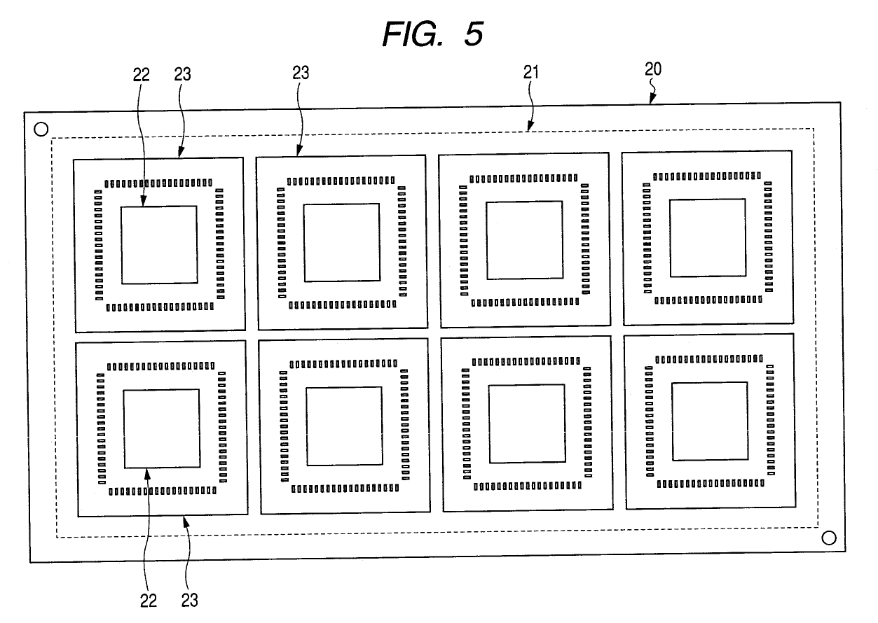

FIG. 5 is a schematic plan view of the multi-wiring substrate used for manufacture of a semiconductor device,

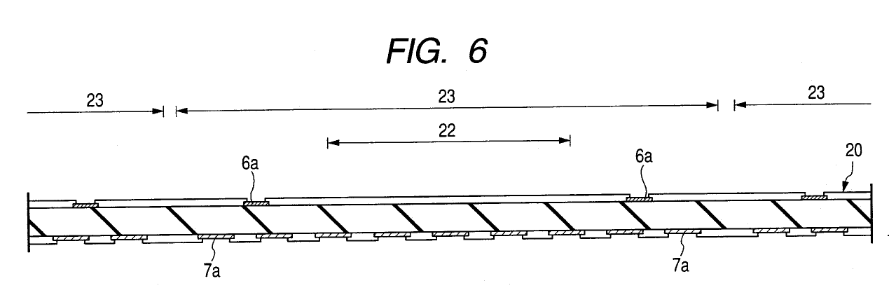

FIG. 6 is a schematic cross-sectional view expanding and showing a part of multi-wiring substrate of FIG. 5,

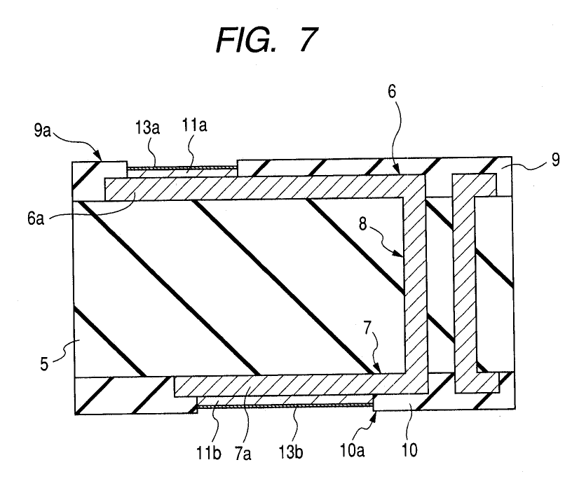

FIG. 7 is the schematic cross-sectional view which expanded a part of FIG. 6,

FIG. 8 is the schematic cross-sectional view which expanded a part of FIG. 7 (electrode pad portion for wire connection),

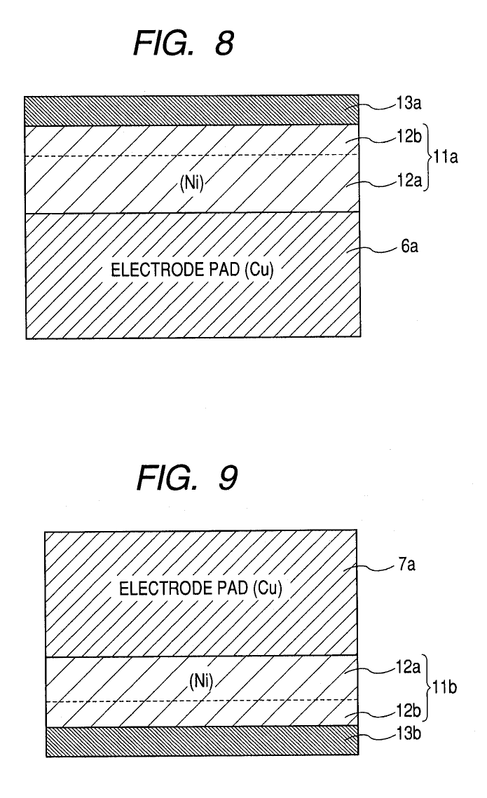

FIG. 9 is the schematic cross-sectional view which expanded a part of FIG. 7 (electrode pad portion for bump connection),

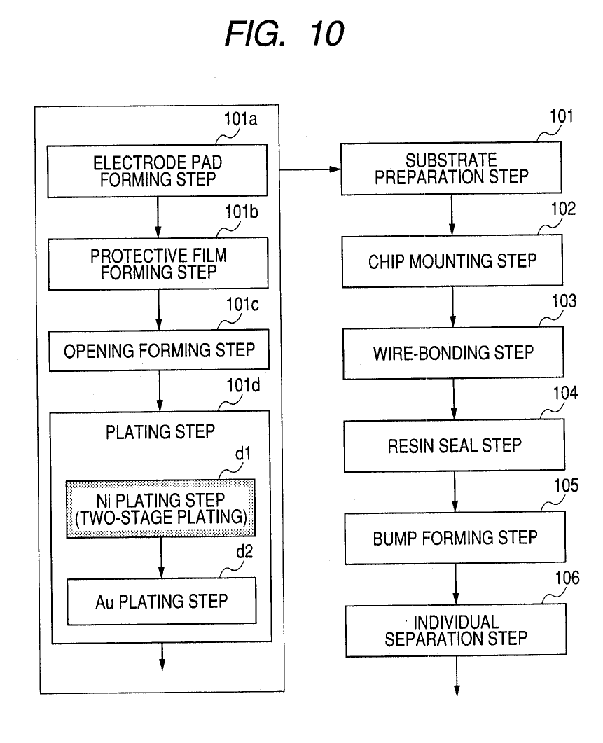

FIG. 10 is a flow chart which shows the manufacturing process of a semiconductor device,

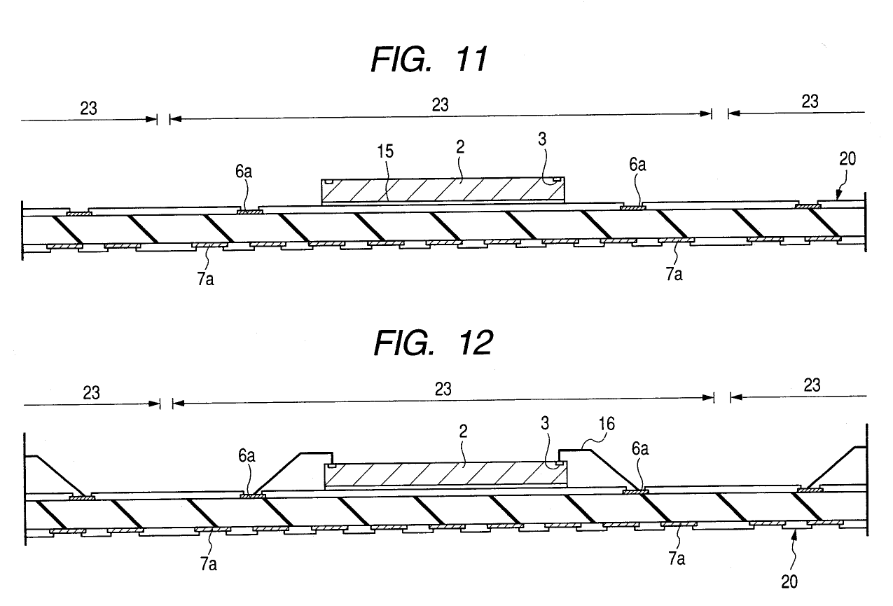

FIG. 11 through FIG. 15 are the schematic cross-sectional views showing the manufacturing process of a semiconductor device,

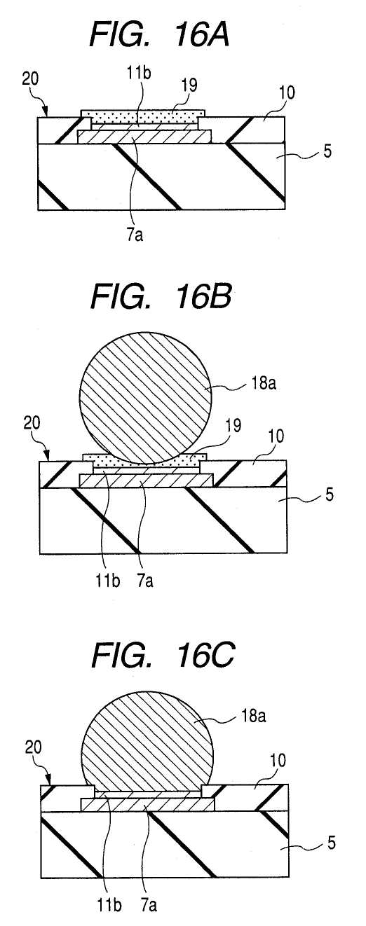

FIGS. 16A to 16C are drawings (FIGS. 16A to 16C are schematic cross-sectional views in each step) for explaining the first bump forming step in manufacture of a semiconductor device, and

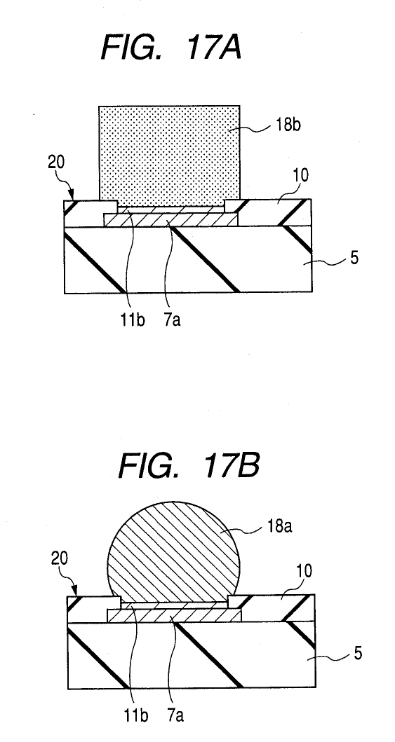

FIGS. 17A and 17B are drawings (FIGS. 17A and 17B are schematic cross-sectional views in each step) for explaining the second bump forming step in manufacture of a semiconductor device.

As shown in FIGS. 1A and 1B, BGA type semiconductor device 1a of Example 1 has package structure by which semiconductor chip 2 was mounted in the main surface 4x side of wiring substrate 4 called an interposer, and a plurality of solder bumps 18 of ball state have been arranged as a terminal for external connection at the back surface 4y side of the opposite side of main surface 4x of wiring substrate 4.

The plane form which intersects the thickness direction is rectangular shape, and semiconductor chip 2 is formed with the square of 5 mm×5 mm by Example 1. Although not limited to this, semiconductor chip 2 has the structure of mainly having semiconductor substrate, a plurality of transistor elements formed in the main surface of this semiconductor substrate, the thin film layered product (multilayer interconnection layer) which accumulated two or more stages of each of the insulating layer and the wiring layer on the main surface of the semiconductor substrate, and the passivation film (the last protective film) formed as covered this thin film layered product. The semiconductor substrate is formed, for example with single crystal silicon. The insulating layer is formed, for example with the silicon oxide film. The wiring layer is formed, for example with metallic films, such as aluminum (Al), an aluminum alloy, copper (Cu), or a copper alloy. The passivation film is formed with the multilayer film which accumulated inorganic insulating films, such as a silicon oxide film or a silicon nitride film, and organic insulating films, such as a polyimide system resin layer, for example.

The control circuit is built in semiconductor chip 2 as an integrated circuit. This control circuit mainly includes the transistor element formed in the main surface of a semiconductor substrate, and the wiring formed in the thin film layered product.

In main surface 2x of semiconductor chip 2, a plurality of electrode pads (bonding pad) 3 are arranged. A plurality of electrode pads 3 are formed in the wiring layer of the top layer of the thin film layered product of semiconductor chip 2, and are exposed by the bonding opening formed in the passivation film of semiconductor chip 2. A plurality of electrode pads 3 are arranged along each side of main surface 2x of semiconductor chip 2.

Adhesion fixing of the semiconductor chip 2 is done to main surface 4x of wiring substrate 4 in the state where binder 15 was intervened between the back surface 2y, and main surface 4x of wiring substrate 4.

The plane form which intersects the thickness direction is rectangular shape, and wiring substrate 4 has a square of 13 mm×13 mm in Example 1. A plurality of electrode pads 6a are arranged in main surface 4x of wiring substrate 4, and a plurality of electrode pads 7a are arranged in back surface 4y of wiring substrate 4. A plurality of electrode pads 6a are arranged around semiconductor chip 2 corresponding to a plurality of electrode pads 3 of semiconductor chip 2. A plurality of electrode pads 7a are arranged in the shape of an array, although not illustrated in detail.

A plurality of electrode pads 3 of semiconductor chip 2 are electrically connected with a plurality of electrode pads 6a of wiring substrate 4 by a plurality of bonding wires 16, respectively. As for bonding wire 16, the one end side is connected to electrode pad 3 of semiconductor chip 2, and the other end side of the opposite side at the side of one end is connected to electrode pad 6a of wiring substrate 4. In Example 1, the gold (Au) wire is used as bonding wire 16, for example. As a connection method of bonding wire 16, the ball-bonding (nailhead bonding) method which used supersonic vibration together to thermocompression bonding is used, for example. Connection of bonding wire 16 is made by the forward bonding method which sets electrode pad 3 of semiconductor chip 2 as primary connection, and sets the electrode pad of wiring substrate 4 as secondary connection.

The resin seal of semiconductor chip 2, a plurality of bonding wires 16, etc. is done by resin sealing body 17 formed on main surface 4x of wiring substrate 4. Resin sealing body 17 includes, as a purpose which aims at stress reduction, the thermosetting insulating resin of the epoxy system with which a phenol system curing agent, silicone rubber, many fillers (for example, silica), etc. were added, for example.

The plane form which intersects a thickness direction is rectangular shape, and resin sealing body 17 has the same plane size as wiring substrate 4 in Example 1. As a formation method of resin sealing body 17, the transfer molding method suitable for mass production is used, for example.

Here, in manufacture of a BGA type semiconductor device, the multi-wiring substrate (multi-chip wiring substrate) which has a plurality of product formation areas (a device formation area, a product acquisition region) divided by the scribe-line is used. The transfer molding method of the individual system which does the resin seal of the semiconductor chip mounted in each product formation area for every product formation area, and the transfer molding method of the batch system which uses the multi-wiring substrate which has a plurality of product formation areas, and does collectively the resin seal of the semiconductor chip mounted in each product formation area by one resin sealing body are adopted. In Example 1, the transfer molding method of the batch system suitable for a miniaturization is adopted, for example.

After forming a resin sealing body in the case of the transfer molding method of a batch system, a multi-wiring substrate and a resin sealing body are divided into a plurality of individual segments by dicing, for example. Therefore, as for resin sealing body 17 and wiring substrate 4 of Example 1, plane size has become almost the same.

Although not limited to this, as shown in FIG. 2, wiring substrate 4 mainly has the structure of having core material (base material) 5, protective film 9 formed as covered the main surface of this core material 5, and protective film 10 formed as covered the back surface of the opposite side of the main surface of this core material 5, for example. Core material 5 consists of a high elasticity resin substrate which did impregnation of the resin of an epoxy system or a polyimide system to glass fiber, for example, and has two-layer wiring structure which has a wiring layer (6, 7) to both faces of the back and front. Each wiring layer (6, 7) of core material 5 is formed, for example with the metallic film with high conductivity which uses Cu as the main ingredients. Protective films 9 and 10 are mainly formed in order to protect the wiring formed in the wiring layer of both faces of core material 5. Protective films 9 and 10 include insulating resin films (solder-resist film), such as 2 acidity-or-alkalinity alkali developing solution type solder-resist ink or heat-curing type 1 acidity-or-alkalinity solder-resist ink, for example.

A plurality of electrode pads 6a of main surface 4x of wiring substrate 4 include a part of each of a plurality of wirings formed in the first wiring layer 6 counting from main surface 4x of wiring substrate 4, and are exposed by opening 9a formed in protective film 9 at the side of main surface 4x of wiring substrate 4.

A plurality of electrode pads 7a of back surface 4y of wiring substrate 4 include a part of each of a plurality of wirings formed in the second wiring layer counting from main surface 4x of wiring substrate 4, and are exposed by opening 10a formed in protective film 10 at the side of back surface 4y of wiring substrate 4.

The wiring formed in the first wiring layer 6 is electrically connected with the wiring formed in the second wiring layer 7 via through hole wiring 8 shown in FIG. 2. That is, electrode pad 6a and electrode pad 7a are electrically connected.

A plurality of solder bumps 18 adhere to a plurality of electrode pads 7a arranged at the back surface 4y of wiring substrate 4, respectively, and are connected to them electrically and mechanically. As solder bump 18, the solder bump of Pb free composition which does not include Pb substantially, for example, the solder bump of Sn—Ag (3[wt %])-Cu (0.5[wt %]) composition, is used.

As shown in FIG. 2, Ni film (11a, 11b) which uses nickel (Ni) as the main ingredients, for example is formed in the front surface of electrode pad 6a, and the front surface of electrode pad 7a as a plating film, respectively. Au film 13a which uses gold (Au) as the main ingredients, for example is formed in the front surface of Ni film Ha as a plating film. These films are formed by the electrolytic plating method.

Au film which uses Au as the main ingredients is formed also in the front surface of electrode pad 3 of semiconductor chip 2. The one end side of bonding wire 16 is joined to Au film on electrode pad 3 of semiconductor chip 2, and the other end side of bonding wire 16 is joined to Au film 13a on electrode pad 6a of wiring substrate 4. That is, bonding wire 16 is connected with electrode pad 3 of semiconductor chip 2, and electrode pad 6a of wiring substrate 4 electrically and mechanically by Au/Au junction on Au wire and Au film.

As shown in FIG. 4, between Ni film 11b and solder bump 18, alloy layer (intermetallic compound layer) 14 of Sn—Ni—Cu composition including these elements is formed. Adherence with electrode pad 7a and solder bump 18 is made by junction with Ni film 11b and solder bump 18 by this alloy layer 14.

As shown in FIG. 4, Ni film 11b has the structure of having first Ni layer 12a formed in the front surface of electrode pad 7a with the first current density (low current density), and the second Ni layer 12b formed in the front surface of this first Ni layer 12a with the second current density (high current density) higher than the first current density. First Ni layer 12a and second Ni layer 12b are continuously formed in Ni plating step. Alloy layer 14 is formed between second Ni layer 12b and solder bump 18.

Since Ni film 11a on electrode pad 6a is formed at the same step as Ni film 11b on electrode pad 7a, as shown in FIG. 3, Ni film 11a on electrode pad 6a as well as Ni film 11b on electrode pad 7a has the structure of having first Ni layer 12a formed in the front surface of electrode pad 6a with the first current density (low current density), and second Ni layer 12b formed in the front surface of this first Ni layer 12a with the second current density (high current density) higher than the first current density. Au film 13a is formed in the front surface of second Ni layer 12b.

In the stage before forming solder bump 18 on electrode pad 7a, as shown in FIG. 7, Au film 13b is formed also in the front surface of Ni film 11b. Since this Au film 13b is generally formed by the thin thickness about 0.5 μm, it disappears by diffusion at the time of a solder bump's formation. Since Au film 13b is formed at the same step as Au film 13a on electrode pad 6a, it is formed in the front surface of second Ni layer 12b like Au film 13a (refer to FIG. 9).

Ni film 11b on electrode pad 7a is formed for the purpose which mainly prevents that the metal of electrode pad 7a is diffused in alloy layer 14 and solder bump 18, and the purpose which raises bondability with solder bump 18. Au film 13b on Ni film 11b is mainly formed in order to prevent oxidization of Ni film 11b.

Ni film ha on electrode pad 6a is formed in order to mainly prevent that electrode pad 6a deforms by the compression bonding load when connecting bonding wire 16. Au film 13a on Ni film 11a is mainly formed for the purpose which prevents oxidization of Ni film 11a, and the purpose which raises bondability with bonding wire 16.

Next, the multi-wiring substrate used for manufacture of BGA type semiconductor device 1a is explained using FIG. 5 through FIG. 9.

As shown in FIG. 5, the plane form which intersects the thickness direction is rectangular shape, and multi-wiring substrate 20 has a rectangle in Example 1. Molding region (resin seal region) 21 is formed in the main surface (chip mounting surface) of multi-wiring substrate 20. In this molding region 21, a plurality of product formation areas (a device formation area, a product acquisition region) 23 divided by the scribe-line (dicing region) are arranged at matrix form. In Example 1, a plurality of product formation areas 23 are arranged, for example in the matrix of 4×2.

In each product formation area 23, as shown in FIG. 5 and FIG. 6, chip mounting region 22 for mounting semiconductor chip 2 is formed. Each product formation area 23 is the same structure and same plane form as wiring substrate 4 shown in FIG. 1 and FIG. 2 fundamentally, and wiring substrate 4 is formed by individually separating each product formation area 23 separately.

In order that multi-wiring substrate 20 may aim at improvement in wire bonding property and solderability, Ni/Au plating treatment is performed to electrode pad 6a to which bonding wire 16 is connected, electrode pad 7a to which solder bump 18 is connected, etc. As shown in FIG. 7, Ni film (11a, 11b) is formed on the surface of an electrode pad (6a, 7a), and Au film (13a, 13b) is formed in the front surface of Ni film (11a, 11b).

As shown in FIG. 7, Ni film 11a and Au film 13a on electrode pad 6a are formed in opening 9a, so that it may not project from the front surface of protective film 9. Similarly, Ni film 11b and Au film 13b on electrode pad 7a are also formed in opening 10a, so that it may not project from the front surface of protective film 10.

Although mentioned above, as shown in FIG. 8 and FIG. 9, Ni film ha on electrode pad 6a and Ni film 11b on electrode pad 7a have the structure of having first Ni layer 12a formed with the first current density (low current density) on the surface of the electrode pad (6a, 7a), and second Ni layer 12b formed in the front surface of this first Ni layer 12a with the second current density (high current density) higher than the first current density. First Ni layer 12a and second Ni layer 12b are continuously formed by an electrolytic plating method in Ni plating step, and are formed at the same step. Au film (13a, 13b) is formed in the front surface of Ni film (11a, 11b) for example, by an electrolytic plating method by a separated process with Ni film.

Next, manufacture of BGA type semiconductor device 1a is explained using FIG. 10 through FIG. 17. In manufacture of BGA type semiconductor device 1a of Example 1, as shown in FIG. 10, a substrate preparation step <101>—an individual separation step <106> are included. In a substrate preparation step <101>, an electrode pad forming step <101a>—a plating step <101d> are included. In a plating step <101d>, Ni plating step <d1> and Au plating step <d2> are included.

First, multi-wiring substrate 20 shown in FIG. 5 and FIG. 6 is prepared (substrate preparation step <101> of FIG. 10). Multi-wiring substrate 20 is formed by giving an electrode pad forming step <101a>—a plating step <101d>, etc. These steps are explained with reference to FIG. 7. An electrode pad forming step <101a> forms in the main surface of core material 5 the wiring including electrode pad 6a, and forms in the back surface of core material 5 the wiring including electrode pad 7b, and forms through hole wiring 8 etc. A protective film forming step <101b> forms a protective film (9, 10) in the main surface and back surface of core material 5. An opening forming step <101c> forms an opening (9a, 10a) in a protective film (9, 10) corresponding to an electrode pad (6a, 7a). In a plating step <101>, Ni plating step <d1> forms Ni film (11a, 11b) on the surface of an electrode pad (6a, 7a). Au plating step <d2> forms Au film (13a, 13b) in the front surface of Ni film (11a, 11b). Ni plating step <d1> is explained in detail later.

Next, in each product formation area 23 of multi-wiring substrate 20, as shown in FIG. 11, binder 15 is intervened and adhesion fixing of the semiconductor chip 2 is done to each chip mounting region 22 (chip mounting step <102> of FIG. 10). Adhesion fixing of semiconductor chip 2 is performed in the state where the back surface of semiconductor chip 2 faces the main surface of multi-wiring substrate 20.

Next, in each product formation area 23 of multi-wiring substrate 20, as shown in FIG. 12, a plurality of electrode pads 3 of semiconductor chip 2 and a plurality of electrode pads 6a of product formation area 23 are electrically connected by a plurality of bonding wires 16, respectively (wire-bonding step <103> of FIG. 10). In this step, semiconductor chip 2 is mounted in each product formation area 23 of multi-wiring substrate 20, respectively.

Here, mounting means the state where adhesion fixing of the electronic parts was done to the substrate, and it electrically connected. Adhesion fixing of the semiconductor chip 2 of Example 1 is done to product formation area 23 of multi-wiring substrate 20 by binder 15, and electrode pad 3 is electrically connected with electrode pad 6a of product formation area 23 by bonding wire 16.

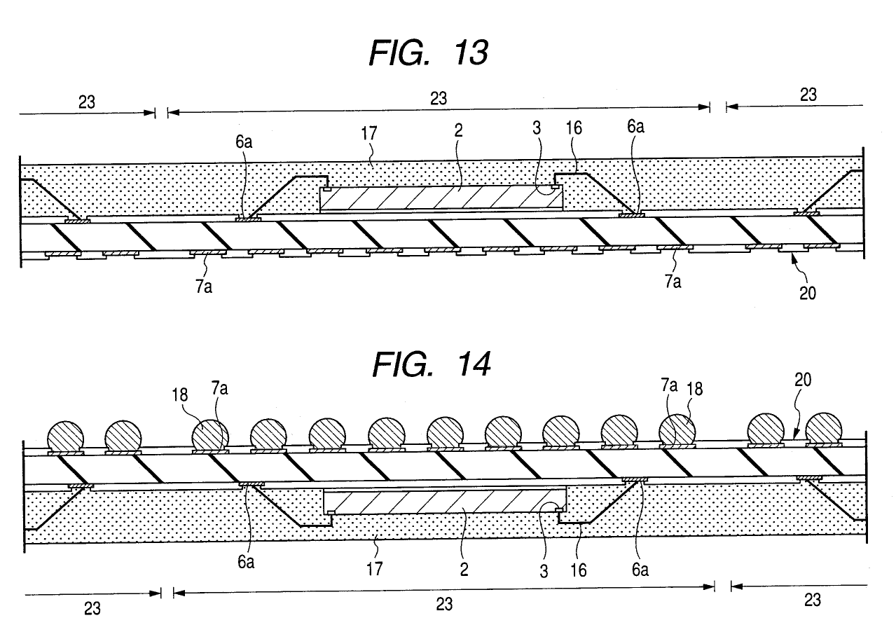

Next, as shown in FIG. 13, using the transfer molding method of a batch system, on the main surface of multi-wiring substrate 20, resin sealing body 17 which does the resin seal of semiconductor chip 2 and the a plurality of bonding wire 16 etc. of each product formation area 23 collectively is formed (resin seal step <104> of FIG. 10).

Next, in each product formation area 23 of multi-wiring substrate 20, as shown in FIG. 14, corresponding to each electrode pad 7a, a plurality of solder bumps 18 are formed on a plurality of electrode pads 7a arranged at the back surface of the opposite side of the main surface of multi-wiring substrate 20.

Here, there are various methods in solder bump's 18 formation. For example, there are a formation method (1) by a solder ball and the method (2) by soldering paste material.

First, the formation method (1) by a solder ball forms flux layer 19 by screen printing on electrode pad 7a (front surface of Au film 13b), as shown in FIG. 16A. Then, as shown in FIG. 16B, solder ball 18a of Sn—Ag—Cu composition is supplied with a suction fixture on electrode pad 7a (on Au film 13b). Then, solder ball 18a is melted and it is made to harden after that. Hereby, as shown in FIG. 16C and FIG. 4, solder bump 18 joined to Ni film 11b is formed on electrode pad 7a. Multi-wiring substrate 20 is transported to, for example an infrared reflow furnace, and melting of solder ball 18a is performed. In the melting process of solder ball 18a, the element in Ni film 11b and the element in solder ball 18a react, and alloy layer (intermetallic compound layer) 14 including these elements is formed (refer to FIG. 4). In the melting process of solder ball 18a, Au film 13b disappears by diffusion.

First, the formation method (2) by soldering paste material forms soldering paste layer 18b by which many solder particles of Sn—Ag—Cu composition were mulled by screen printing on electrode pad 7a (front surface of Au film 13b), as shown in FIG. 17A. Then, soldering paste layer 18b is melted and it is made to harden after that. Hereby, as shown in FIG. 17B and FIG. 4, solder bump 18 joined to Ni film 11b is formed on electrode pad 7a. Solder bump 18 is formed in ball state of the surface tension of the melted solder. Multi-wiring substrate 20 is transported to, for example an infrared reflow furnace, and melting of soldering paste layer 18b is performed. In the melting process of soldering paste layer 18b, the element in Ni film 11b and the element in soldering paste layer 18b react, and alloy layer (intermetallic compound layer) 14 including these elements is formed (refer to FIG. 4). In the melting process of soldering paste layer 18b, Au film 8 disappears by diffusion.

There is also a method of using the solder ball and soldering paste layer (previous soldering) other than a method (1) and (2) which were mentioned above in solder bump's 18 formation. Although not illustrated, this method forms a soldering paste layer by screen printing first on electrode pad 7a (front surface of Au film 13b). Then, a solder ball is supplied with a suction fixture on electrode pad 7a (on Au film 13b). Then, a soldering paste layer is melted and it is made to harden after that. Hereby, solder bump 18 joined to Ni film 11b is formed on electrode pad 7a.

Next, the flux used in the bump forming step <105> is removed by cleaning. Then, corresponding to each product formation area 23 of multi-wiring substrate 20, distinguishing marks, such as a name of article, a company name, a kind, and a manufacture lot number, are formed in the upper surface of resin sealing body 17 using the ink jet marking method, a direct printing method, the laser marking method, etc., for example.

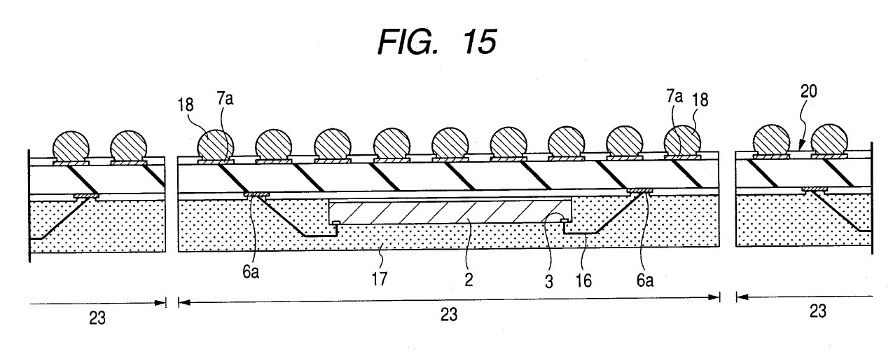

Next, as shown in FIG. 15, multi-wiring substrate 20 and resin sealing body 17 are divided into a plurality of individual segments corresponding to each product formation area 23 (individual separation step <106> of FIG. 10). This division is performed by doing dicing of multi-wiring substrate 20 and the resin sealing body 7a by a dicing blade along the scribe-line of multi-wiring substrate 20, for example. According to this step, BGA type semiconductor device 1a shown in FIG. 1 and FIG. 2 is completed mostly.

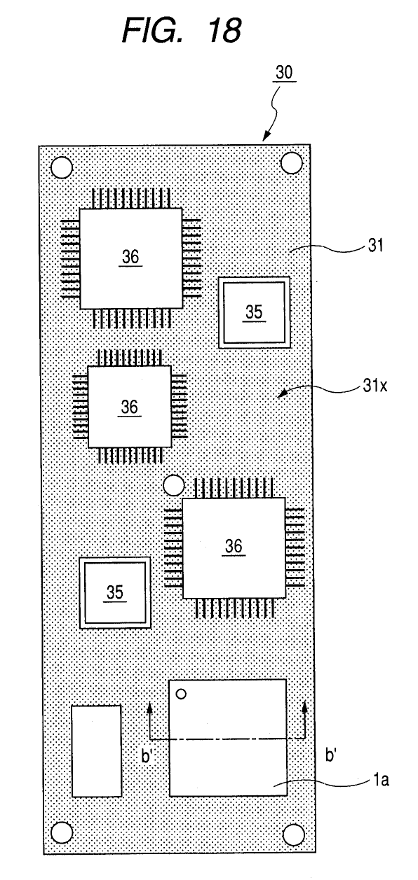

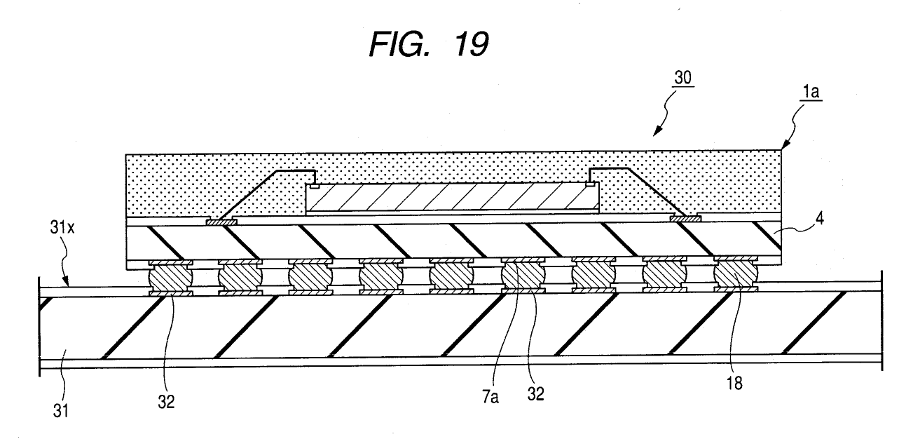

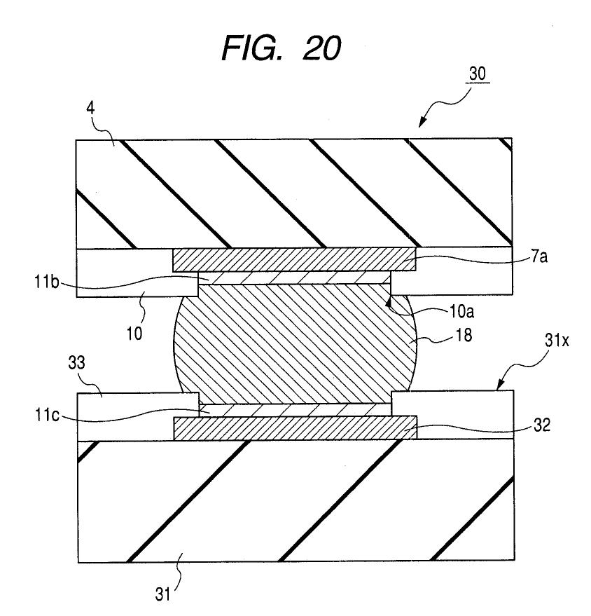

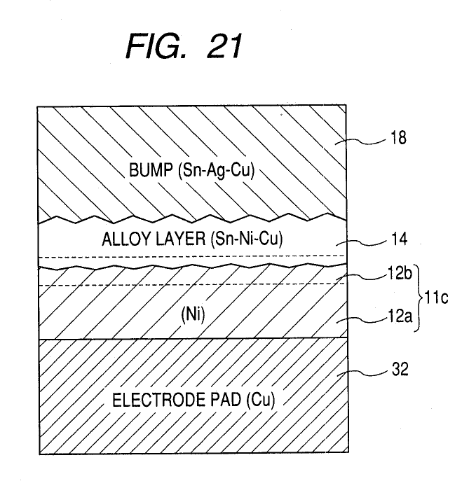

FIG. 18 is a schematic plan view showing the outline structure of the module (electronic device) incorporating BGA type semiconductor device 1a. FIG. 19 is a schematic cross-sectional view which goes along b′-b′ line of FIG. 18. FIG. 20 is the schematic cross-sectional view which expanded a part of FIG. 19. FIG. 21 is the schematic cross-sectional view which expanded a part of FIG. 20.

As shown in FIG. 18, module 30 has the structure of having mounted BGA type semiconductor device 1a, the BGA type semiconductor device 35, and QFP (Quad Flatpack Package) type semiconductor device 36 in the main surface 31x side of mounting substrate 31 as electronic parts.

Although not limited to this, mounting substrate 31 has the structure of mainly having a core material, the protective film (reference 33 shown in FIG. 20) formed as covered the main surface of this core material, and the protective film formed as covered the back surface of the opposite side of the main surface of this core material. The core material has the multilayer interconnection structure of having a wiring, for example in both faces of the back and front, and an inside. Each insulating layer of the core material is formed, for example by the high elasticity resin substrate to which glass fiber was made to do impregnation of the resin of an epoxy system or a polyimide system. Each wiring layer of the core material is formed with the metallic film which uses Cu as the main ingredients, for example. The protective film on the main surface of a core material (33) is formed in order to mainly protect the wiring formed in the wiring layer of the top layer of a core material. The protective film on the back surface of a core material is formed in order to mainly protect the wiring formed in the wiring layer of the undermost layer of a core material. The protective film on a main surface and the protective film on a back surface of the core material are formed, for example in 2 acidity-or-alkalinity alkali developing solution type solder-resist ink or heat-curing type 1 acidity-or-alkalinity solder-resist ink.

In the main surface of mounting substrate 31, as shown in FIG. 19, in the element placement region in which BGA type semiconductor device 1a is mounted, a plurality of electrode pads 32 are arranged corresponding to a plurality of terminals for external connection of BGA type semiconductor device 1a (solder bump 18). Although not illustrated, corresponding to a plurality of terminals for external connection of BGA type semiconductor device 35 (solder bump), a plurality of electrode pads are arranged also to the element placement region in which BGA type semiconductor device 35 is mounted. Corresponding to a plurality of terminals for external connection of QFP type semiconductor device 36 (tip portion of the lead projected from the side surface of a sealing body), a plurality of electrode pads are arranged also to the element placement region in which QFP type semiconductor device 36 is mounted. These electrode pads include a part of each of a plurality of wirings formed in the wiring layer of the top layer of a core material, and are exposed by the opening formed in the protective film (33) on the main surface of a core material.

As shown in FIG. 20, a plurality of solder bumps 18 intervene, respectively between a plurality of electrode pads 7a of BGA type semiconductor device 1a, and a plurality of electrode pads 32 of mounting substrate 31, adhere to electrode pad 7a and electrode pad 32, respectively, and are connected to them electrically and mechanically.

Ni film 11c which uses nickel (Ni) as the main ingredients, for example is formed in the front surface of electrode pad 32 as a plating film.

As shown in FIG. 21, between Ni film 11c and solder bump 18, alloy layer (intermetallic compound layer) 14 of the Sn—Ni—Cu composition including these elements is formed. Adherence with electrode pad 32 and solder bump 18 is made by junction with Ni film 11c and solder bump 18 by this alloy layer 14.

As shown in FIG. 21, like Ni film 11b of wiring substrate 4, Ni film 11c has the structure of having first Ni layer 12a formed in the front surface of electrode pad 32 with the first current density (low current density), and second Ni layer 12b formed in the front surface of this first Ni layer 12a with the second current density (high current density) higher than the first current density. First Ni layer 12a and second Ni layer 12b are continuously formed in the plating step. Alloy layer 14 is formed between second Ni layer 12b and solder bump 18.

Au film is formed also in the front surface of Ni film 11c in the stage before joining solder bump 18 to electrode pad 32. Since this Au film is generally formed by the thin thickness about 0.5 μm, it disappears by diffusion at the time of solder bump's 18 junction (at the time of mounting of BGA type semiconductor device 1a).

Ni film 11c on electrode pad 32 is mainly formed for the purpose which prevents that the metal of electrode pad 32 is diffused in alloy layer 14 and solder bump 18, and the purpose which raises bondability with solder bump 18. Au film on Ni film 11c is mainly formed in order to prevent oxidization of Ni film 11c.

Module 30 mounts electronic parts including BGA type semiconductor devices 1a and 35 and QFP type semiconductor device 36 in main surface 31x of mounting substrate 31, and is formed by mounting these electronic parts collectively by the reflow method after that.

Mounting of BGA type semiconductor device 1a is performed by the following steps. First, a flux layer is formed by screen printing on electrode pad 32 arranged to the element placement region of main surface 31x of mounting substrate 31. Then, BGA type semiconductor device 1a is arranged on an element placement region so that solder bump 18 may be located on electrode pad 32. Then, mounting substrate 31 is transported to, for example an infrared reflow furnace, solder bump 18 is melted, and solder bump 18 which melted is hardened after that.

In the assembling step of this BGA type semiconductor device 1a, the element in Ni film 11c on electrode pad 32 of mounting substrate 31 and the element in the melted solder react, and as shown in FIG. 21, alloy layer 14 including these elements is formed. In the assembling step of this BGA type semiconductor device 1a, Au film on Ni film 11c disappears by diffusion.

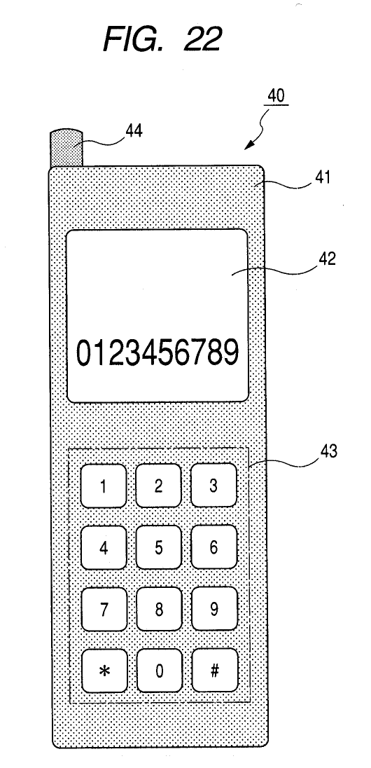

FIG. 22 is a schematic plan view showing the outline structure of the cellular phone (portable electronic apparatus) incorporating module 30.

As shown in FIG. 22, cellular phone 40 has case 41, displaying unit 42, key operation section 43, antenna 44, etc., and case 41 includes a whole surface case and a back surface case. The liquid crystal display, module 30, etc. are included in the inside of this case 41.

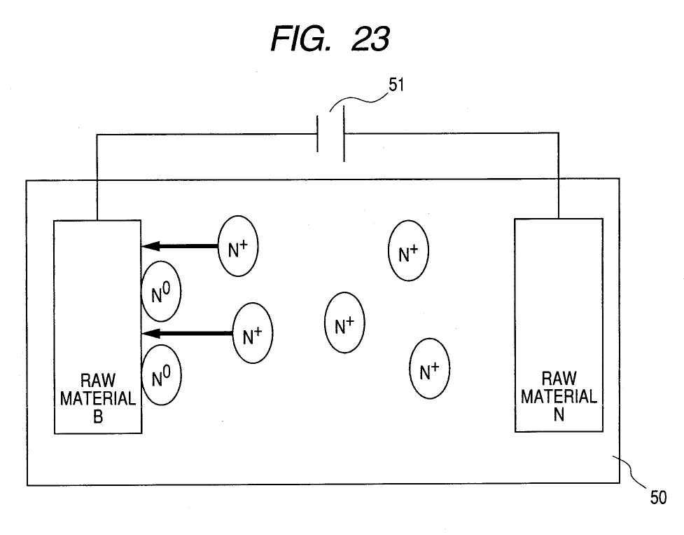

Next, Ni plating step <d1> in a plating step <101d> is explained using FIG. 23. FIG. 23 is a drawing for explaining the electrolytic plating method.

Ni film (11a, 11b) is formed by an electrolytic plating method. An electrolytic plating method is the method of doing electrolytic deposition of the metal to plating treatment material (electric conductor front surface) from a plating solution (metal salt solution) by an electrolysis reaction, and forming a metallic film (plating film). Formation of Ni film is performed as being shown in FIG. 23. Raw material B (multi-wiring substrate 20) is dipped into plating solution 50. Raw material N (solid nickel metal) arranged in plating solution 50 is electrically connected to the anode plate of direct current power supply 51 for electrolysis. Raw material B (electrode pads 6a and 7a of multi-wiring substrate 20) is electrically connected to the cathode of direct current power supply 51 for electrolysis. Generally as plating solution 50, the plating solution which melted a nickel chloride (NiCl), nickel sulfate (NiSO₄), and boric acid is used.

In this Ni plating step <d1>, formation of Ni film (11a, 11b) changes current density (a current value/plating area), and is performed in two steps. First Ni layer 12a is formed on the surface of an electrode pad (6a, 7a) by low current density with small variation in thickness concretely first. Then, second Ni layer 12b is continuously formed in the front surface of first Ni layer 12a with high current density with little incorporation of the impurity to the inside of a film.

In Example 1, the aim value of the thickness of Ni film (11a, 11b) was set to 3 μm, the aim value of the thickness of first Ni layer 12a was set to 2 μm, and the aim value of the thickness of second Ni layer 12b was set to 1 μm. First Ni layer 12a was formed on the conditions of the low current density of 0.37 [A/dm²], and plating time 26.7 [minutes]. Second Ni layer 12b was formed on the conditions of the high current density of 1.5 [A/dm²], and plating time 3.33 [minutes].

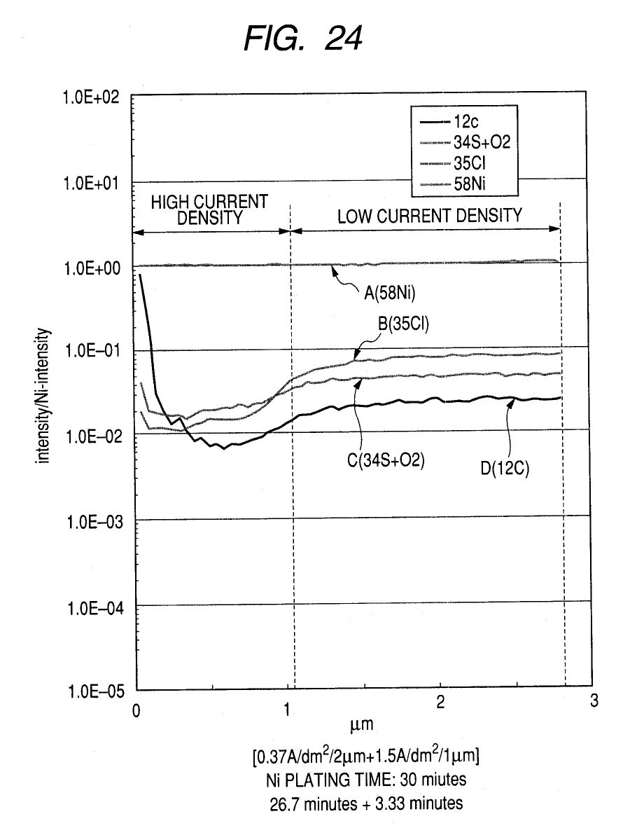

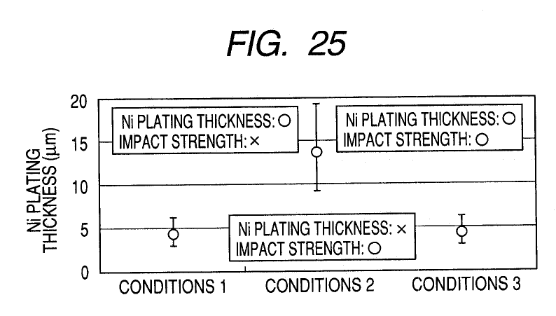

FIG. 24 is a drawing showing the concentration distribution of the impurity included in Ni film lib formed on the above-mentioned conditions. In a drawing, a horizontal axis is the depth from the front surface of Ni film 11b, and a vertical axis is the impurity concentration expressed with the ratio over Ni film ion number of counts in secondary ion mass spectrometry (SIMS). Among a drawing, data B is chlorine (35Cl), data C is sulfur (34S+O2) as an impurity, and data D is carbon (C). Although it is not an impurity, data A is nickel (58Ni).

As shown in FIG. 24, the impurity concentration in second Ni layer 12b formed with the high current density of 1.5 [A/dm²] is lower than the impurity concentration in first Ni layer 12a formed by the low current density of 0.37 [A/dm²]. Chlorine is the highest among chlorine, sulfur, and carbon which are included in Ni layer 12a formed by low current density.

Although chlorine concentration is high by the surface layer part (surface layer part of second Ni layer 12b) of Ni film 11b, since measured Ni film 11b had not formed Au film 13b in a front surface, it is presumed to be what is depended on the contamination under measurement.

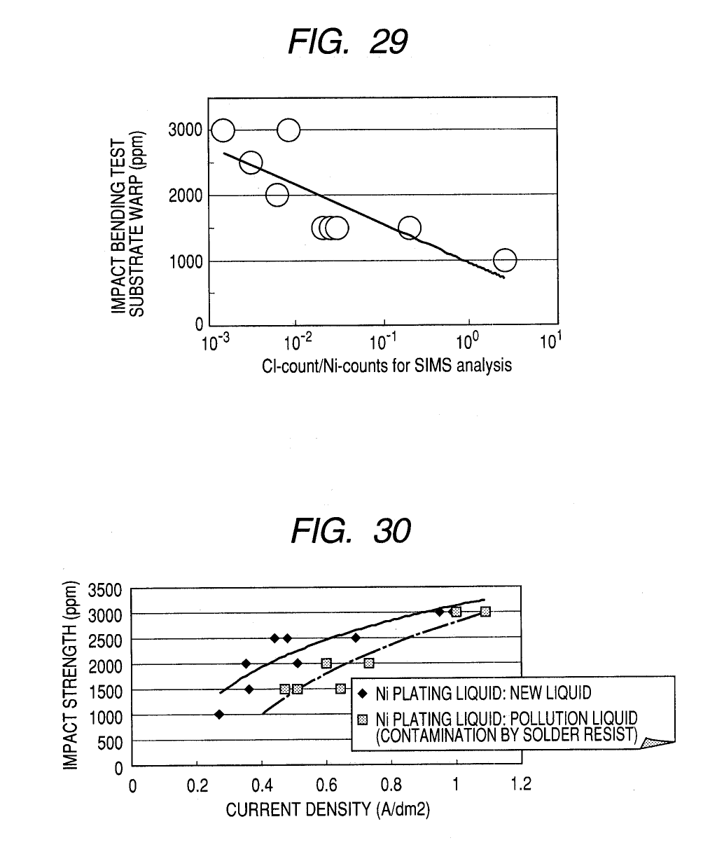

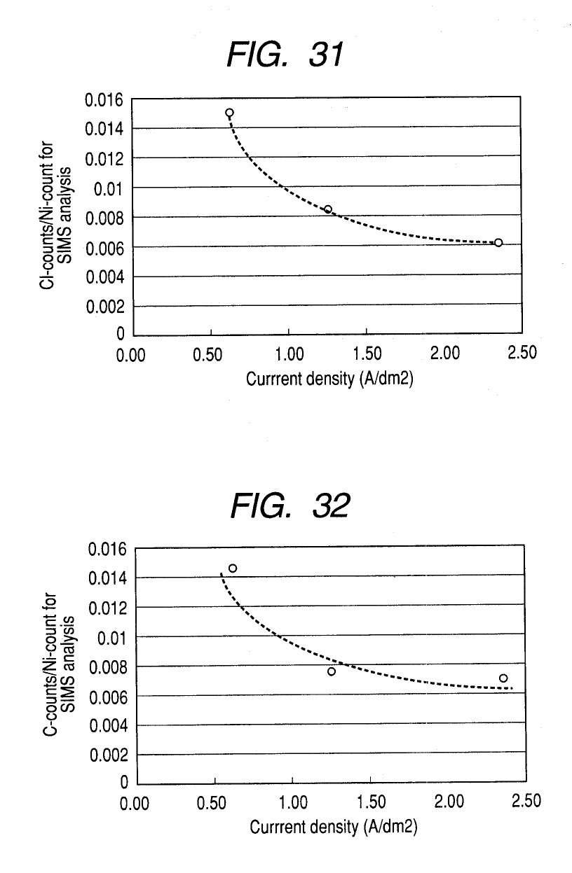

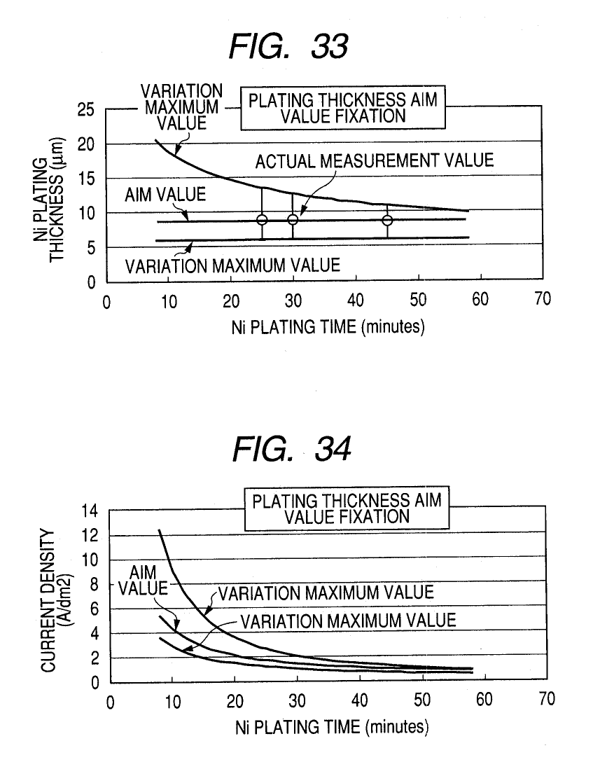

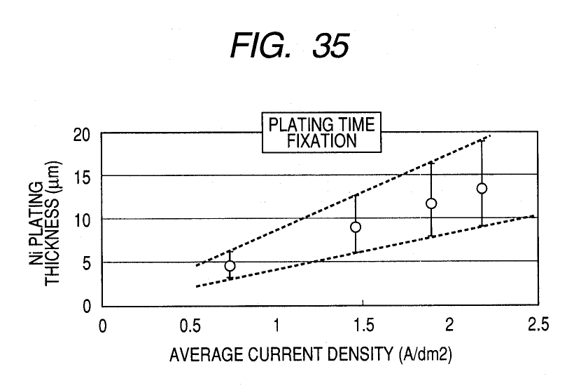

Here, the shock-resistant strength of a soldered joint will become high when the concentration of the impurity included in Ni film becomes low (refer to FIG. 29). The concentration of the impurity included in Ni film will become low when raising the current density when forming Ni film (refer to FIG. 31 and FIG. 32). From this, the shock-resistant strength of a soldered joint becomes high by forming Ni film with high current density (refer to FIG. 30). As shown in FIG. 4, junction with Ni film 11b and solder bump 18 is performed by forming between these alloy layer (intermetallic compound layer) 14 of the Sn—Ni—Cu composition including these elements. Therefore, the shock-resistant strength of a soldered joint can be raised by forming the region which contributes to a soldering joint in the depth direction of Ni film 11b with high current density with little incorporation of the impurity to the inside of a film. As for Ni film 11b of Example 1, second Ni layer 12b that contributes to junction with solder bump 18 is formed with high current density.

On the other hand, the variation in the thickness of Ni film will become low when lowering the current density when forming Ni film. Ni film 11b of Example 1 has 2 layer structure of first Ni layer 11a formed by low current density, and second Ni layer 11b formed with high current density. Therefore, by the part corresponding to first Ni layer 11a, the height variation of Ni film 11b can be reduced as compared with Ni film of the monolayer formed with high current density.

Thus, in the step (Ni plating step <d1>) which forms Ni film (11a, 11b) on an electrode pad (6a, 7a), first Ni layer 12a with small variation in thickness is formed with the first current density (low current density). Then, second Ni film 12b with little incorporation of an impurity is formed with the second current density (high current density) higher than the first current density. Hereby, the improvement in shock-resistant strength of a soldered joint (junction of electrode pad 7a and solder bump 18) is realizable, and the variation in the thickness of Ni film 11b formed in the front surface of electrode pad 7a can be reduced.

Since the variation in the thickness of Ni film 11b formed in the front surface of electrode pad 7a can be reduced, the height variation of solder bump 18 resulting from the variation in the thickness of Ni film 11b can be reduced, and improvement in mounting reliability of BGA type semiconductor device 1a can be aimed at.

In Ni plating step <d1>, the same Ni film Ha as Ni film 11b is formed also in the front surface of electrode pad 6a to which bonding wire 16 is connected. Therefore, since the thickness variation of this Ni film Ha is also reduced, the connection failure of bonding wire 16 resulting from the variation in the thickness of Ni film Ha can be suppressed, and improvement in a manufacturing yield of BGA type semiconductor device 1a can be aimed at.

Since the thickness variation of Ni film (11a, 11b) on an electrode pad (6a, 7b) can be reduced, the trouble that Au film (13a, 13b) and Ni film (11a, 11b) project rather than the front surface of a protective film (9, 10) can be suppressed. As a result, since the trouble “In manufacture of a semiconductor device, a wiring substrate may be managed in piles. When Au film and Ni film have projected rather than the protective film, in the overlapping wiring substrate of two sheets, a blemish is attached to the protective film of both wiring substrates. In the case of a blemish which has a bad influence on wiring protection, a wiring substrate becomes defective.” can be suppressed, the manufacturing cost of BGA type semiconductor device 1a can be reduced.

The depth of alloy layer 14 formed in Ni film 11b is about 1 [μm] in general from the front surface of Ni film 11b. Therefore, as for the thickness of second Ni layer 12b that contributes to a soldering joint, doing more than 1 [μm] is desirable. However, since the thickness of first Ni layer 12a will become thick when thickness of second Ni layer 12b is made thin when thickness of Ni film 11b is fixed, the variation in the thickness of Ni film 11b will increase. Therefore, as for the thickness of second Ni layer 12b, it is desirable to set up in consideration of the depth of alloy layer 14 and the degree of variation of thickness of Ni film 11b.

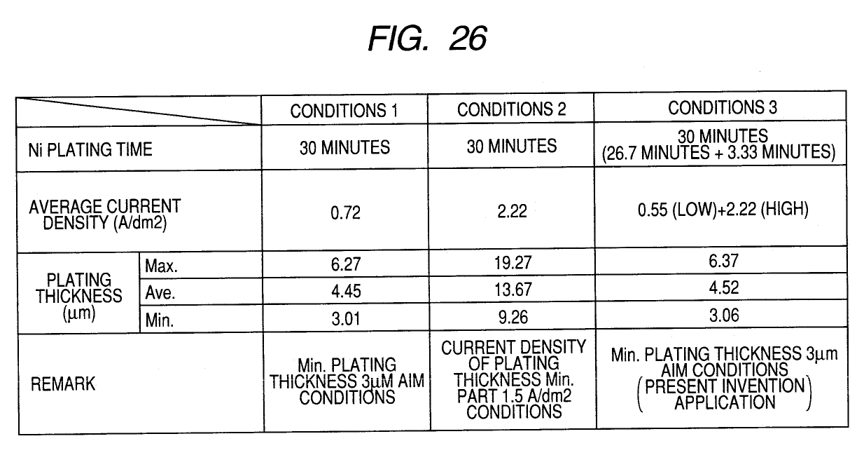

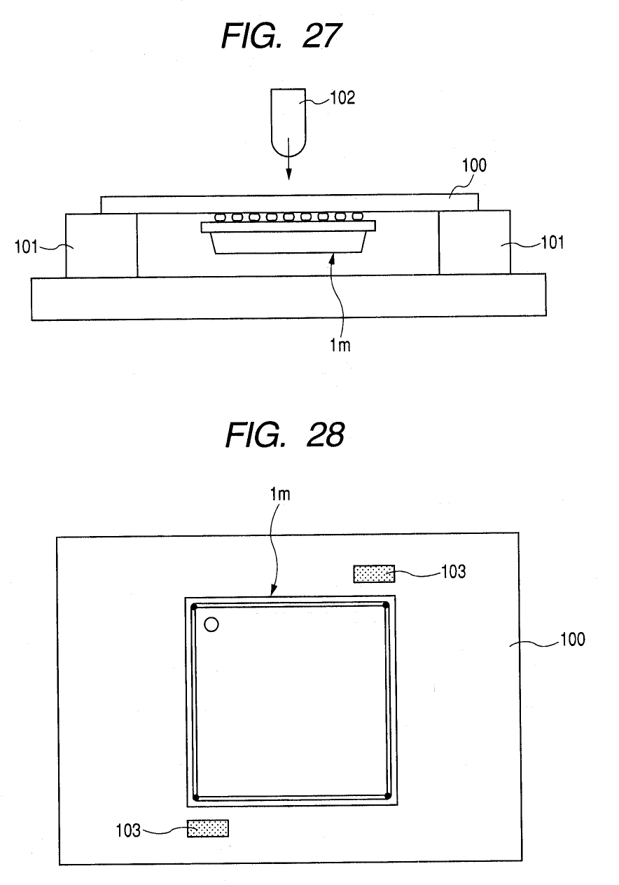

FIG. 25 is a drawing showing the thickness of Ni film when fixing plating time in 30 minutes and forming Ni film on conditions of 1-3. FIG. 26 is the drawing which made the table conditions 1-3 of FIG. 25.

As shown in FIG. 25, on conditions 1 which form Ni film by low current density (0.72 [A/dm²]), the thickness of Ni film becomes thin, but shock-resistant strength becomes low. On conditions 2 which form Ni film with high current density (2.22 [A/dm²]), although the thickness of Ni film becomes thick, shock-resistant strength becomes high. On conditions 3 which form Ni film with low current density (0.55 [A/dm²]) and high current density (2.22 [A/dm²]), the thickness of Ni film becomes thin and shock-resistant strength becomes high.

From this, first Ni layer 12a with small variation in thickness is formed with the first current density (low current density) in the step (Ni plating step <d1>) which forms Ni film (11a, 11b) on an electrode pad (6a, 7a). Then, second Ni layer 12b with little incorporation of an impurity is formed by the thickness which contributes as alloy layer 14 with the second current density (high current density) higher than the first current density. Even when plating time is fixed and it thereby forms Ni film, improvement in shock-resistant strength of a soldered joint can be realized, and thickness reduction of Ni film can be aimed at. Here, in Example 1, the thickness of second Ni layer 12b is formed more thinly than the thickness of first Ni layer 12a. When the thickness of a protective film (9, 10) also becomes thin with the further miniaturization (thickness reduction) of a semiconductor device, the total thickness of Ni (11a, 11b) must also be formed more thinly. However, in order to realize improvement in shock-resistant strength of a soldered joint, even if solder bump's 18 diameter becomes small, as to the thickness which contributes as alloy layer, about 14, 1 μm is required. Therefore, at least, it is preferred to form second Ni layer 12b with little incorporation of an impurity with the second current density (high current density) higher than the first current density. Therefore, the thickness of second Ni layer 12b may be formed more thickly than the thickness of first Ni layer 12a.

Since thickness reduction of Ni film can be aimed at, the trouble that Au film (13a, 13b) and Ni film (11a, 11b) project rather than the front surface of a protective film (9, 10) can be suppressed. As a result, since the trouble “In manufacture of a semiconductor device, a wiring substrate may be managed in piles. When Au film and Ni film have projected rather than the protective film, in the overlapping wiring substrate of two sheets, a blemish is attached to the protective film of both wiring substrates. In the case of a blemish which has a bad influence on wiring protection, a wiring substrate becomes defective.” can be suppressed, the manufacturing cost of BGA type semiconductor device 1a can be reduced.

Setting up the thickness of Ni film thinly can also realize thickness reduction of Ni film. However, when the thickness of Ni film is set up thinly, in Ni film 11b, the barrier function to prevent that the atom of electrode pad 7a is diffused to alloy layer 14 will fall. In Ni film 11a, the function to prevent that electrode pad 6a deforms by the compression bonding load when connecting bonding wire 16 to electrode pad 6a will fall. In order to secure the barrier function to prevent diffusion, and the function to prevent deformation of electrode pad 6a, the thickness of at least 3 [μm] is needed. Therefore, in order to secure these functions and to aim at thickness reduction of Ni film, the method explained by Example 1 is effective.

BGA type semiconductor device 1a is mounted in mounting substrate 31 by joining solder bump 18 to Ni film 11c on electrode pad 32 of mounting substrate 31, as shown in FIG. 20. Therefore, in forming Ni film 11c by an electrolytic plating method on electrode pad 32 of a mounting substrate, it makes Ni film 11c as well as Ni film 11b on electrode pad 7a into 2 layer structure (from the electrode pad 32 side, Ni layer 12 a/nickel layer 12b) which differs in the current density at the time of plating. Hereby, the improvement in shock-resistant strength of the soldered joint (junction of solder bump 18 and electrode pad 32) after mounting in a mounting substrate is realizable. The variation in the thickness of Ni film 11c can be reduced, and the thickness of Ni film 11c can be reduced further.

### Example 2

This Example 2 explains the example which applied the present invention to the LGA type semiconductor device.

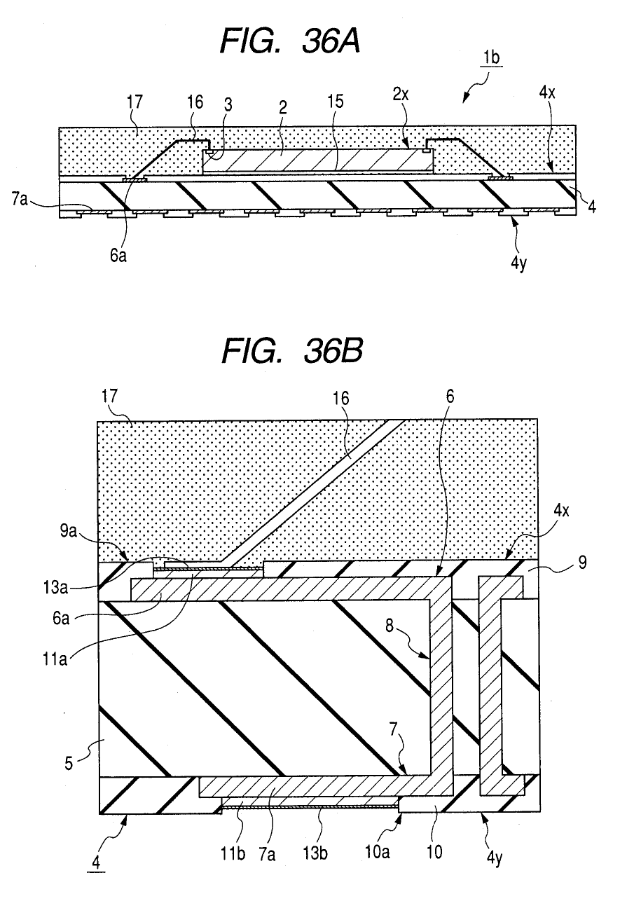

FIGS. 36A and 36B are drawings (FIG. 36A is a schematic cross-sectional view showing the whole structure, and FIG. 36B is the schematic cross-sectional view which expanded a part of FIG. 36A) showing the internal structure of the semiconductor device which is Example 2 of the present invention.

As shown in FIG. 36A, LGA type semiconductor device 1b has package structure by which semiconductor chip 2 was mounted in the main surface 4x side of wiring substrate 4, and a plurality of electrode pads 7a have been arranged as a terminal for external connection at the back surface 4y side of wiring substrate 4.

Ni/Au plating treatment by an electrolytic plating method is performed to electrode pads 6a and 7a. As shown in FIG. 36B, Ni film (11a, 11b) is formed in each front surface of electrode pads 6a and 7a, and Au film (13a, 13b) is formed in the front surface of each Ni film, respectively. Ni film (11a, 11b) has structure including first Ni layer 12a formed of the first current density (low current density) on the surface of the electrode pad (6a, 7a), and second Ni layer 12b formed of the second current density (high current density) higher than the first current density.

Between electrode pad 7a, and the electrode pad of a mounting substrate, a solder layer is intervened and LGA type semiconductor device 1b is mounted in a mounting substrate. Therefore, also in LGA type semiconductor device 1b without a solder bump, by making Ni film 11b on electrode pad 7a into 2 layer structure (from the electrode pad 7a side, Ni layer 12a/Ni layer 12b) which differs in the current density at the time of plating like the above-mentioned Example 1, the improvement in shock-resistant strength of the soldered joint after mounting in a mounting substrate is realizable, and the variation in the thickness of Ni film (11a, 11b) can be reduced, and the thickness of Ni film (11a, 11b) can be reduced further.

### Example 3

Example 3 explains the example which applied the present invention to the BGA type semiconductor device of face-down-bonding structure.

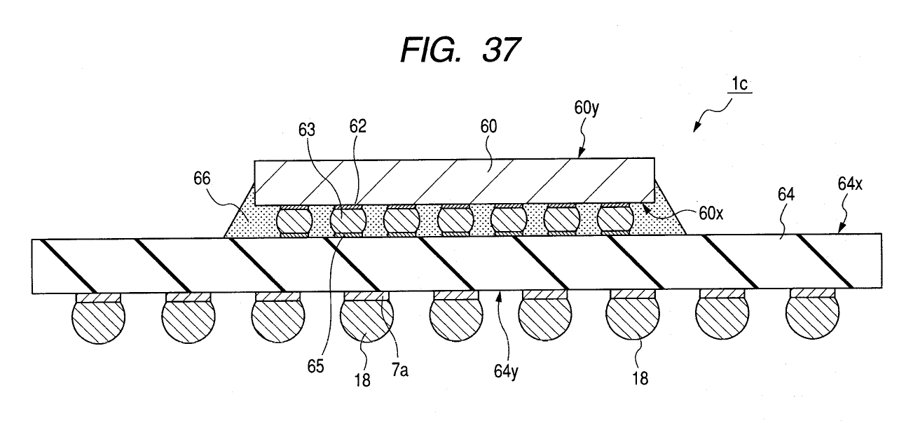

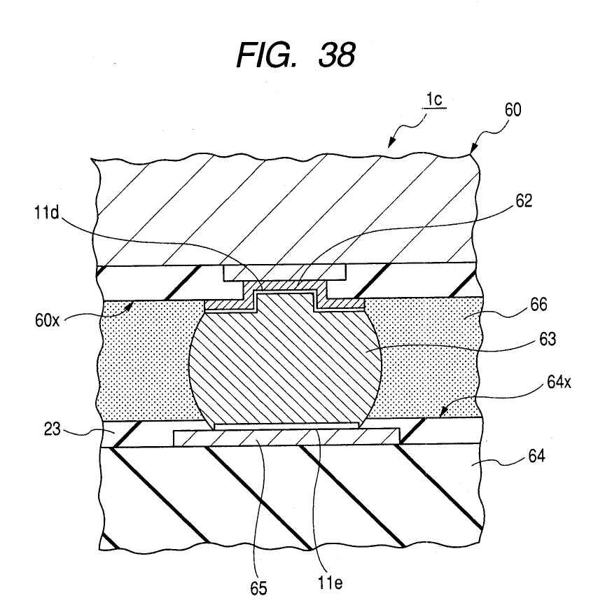

FIG. 37 is a schematic cross-sectional view showing the outline structure of the BGA type semiconductor device which is Example 3 of the present invention, and FIG. 38 is the schematic cross-sectional view which expanded a part of FIG. 37.

As shown in FIG. 37, BGA type semiconductor device 1c has package structure by which semiconductor chip 60 was mounted in the main surface 64x side of wiring substrate 64, and a plurality of solder bumps 18 of ball state have been arranged as a terminal for external connection at the back surface 64y side of wiring substrate 64.

A plurality of electrode pads 62 are arranged in main surface 60x of semiconductor chip 60. In main surface 64x of wiring substrate 64, corresponding to a plurality of electrode pads 62 of semiconductor chip 60, a plurality of electrode pads 65 are arranged, and a plurality of electrode pads 7a are arranged at back surface 64y of wiring substrate 64. Solder bump 18 adheres to electrode pad 7a.

Semiconductor chip 60 is mounted in main surface 64x of wiring substrate 64 in the state where the main surface 60x faces main surface 64x of wiring substrate 64. Electrode pad 62 of semiconductor chip 60 and electrode pad 65 of wiring substrate 64 are connected electrically and mechanically via solder bump 63 between these. Solder bump 63 adheres to electrode pads 62 and 65.

As shown in FIG. 38, Ni films 11d are formed in the front surface of electrode pad 62, and Ni film 11e is formed in the front surface of electrode pad 65. Ni films lid and 11e have the same structure as Ni film 11b of the above-mentioned Example 1. That is, they have 2 layer structure by which first Ni layer 12a was formed on the surface of the electrode pad, and second Ni layer 12b was formed in the front surface of first Ni layer 12a. The solder bump of lead free composition is used as solder bump 63. Resin 66 called under-filling fills up between semiconductor chip 60 and wiring substrate 64.

It is joined to Ni films 11d on electrode pad 62, and solder bump 63 is joined to Ni film 11e on electrode pad 65.

Thus, Ni films 11d on electrode pad 62 and Ni film 11e on electrode pad 65 are made into 2 layer structure (from the electrode pad 7a side, Ni layer 12a/Ni layer 12b) which differs in the current density at the time of plating like the above-mentioned Example 1. Hereby, also in Example 3, the improvement in shock-resistant strength of a soldered joint is realizable, and the variation in the thickness of Ni film (11d, 11e) can be reduced, and the thickness of Ni film (11d, 11e) can be reduced further.

### Example 4

Example 4 explains the example which applied the present invention to the CSP (Chip Size Package) type semiconductor device.

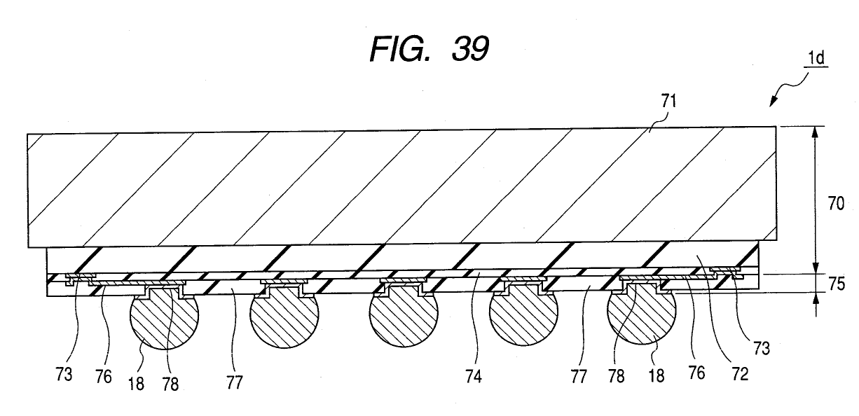

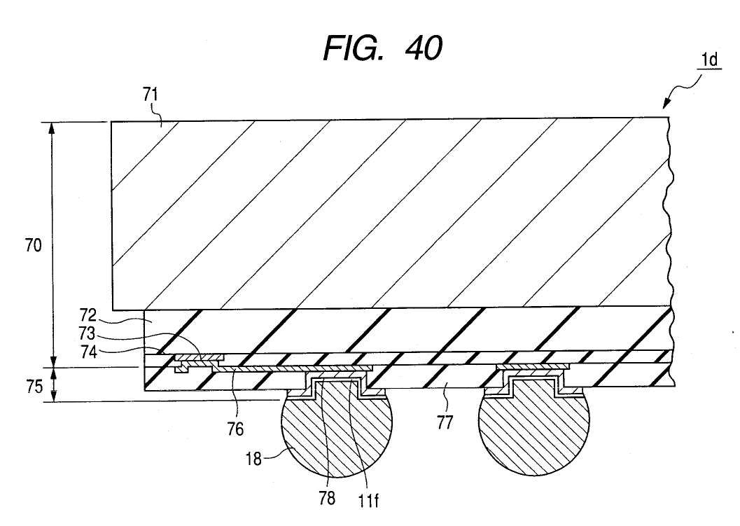

FIG. 39 is a cross-sectional view showing the outline structure of the semiconductor device which is Example 4 of the present invention, and FIG. 40 is the principal part cross-sectional view which expanded a part of FIG. 39.

As shown in FIG. 39 and FIG. 40, CSP type semiconductor device 1d of Example 4 has the structure of mainly having semiconductor chip layer 70, rewiring layer 75 formed on the main surface of this semiconductor chip layer 70 (pad rearrangement layer), and a plurality of solder bumps 18 arranged on this rewiring layer 75.

Semiconductor chip layer 70 mainly has the structure of having semiconductor substrate 71, multilayer interconnection layer 72 which accumulated two or more stages of each of the insulating layer and the wiring layer on the main surface of this semiconductor substrate 71, and passivation film 74 formed as covered this multilayer interconnection layer 72. Semiconductor substrate 71 is formed with single crystal silicon, and the insulating layer of multilayer interconnection layer 72 is formed with the silicon oxide film. The wiring layer of multilayer interconnection layer 72 is formed by the aluminum (Al) film or an aluminum alloy film, and passivation film 74 is formed with the silicon nitride film.

A plurality of electrode pads 73 are formed in the main surface of semiconductor chip layer 70, and these electrode pads 73 of a plurality of are arranged along two sides which face mutually of CSP type semiconductor device 1d. Each of a plurality of electrode pads 73 is formed in the wiring layer of the top layer of multilayer interconnection layer 72. The wiring layer of the top layer of multilayer interconnection layer 72 is covered with passivation film 74 formed in the upper layer, and the opening which exposes the front surface of electrode pad 73 is formed in this passivation film 74.

Rewiring layer 75 has the structure of mainly having the insulating layer formed on passivation film 74 (not shown), a plurality of wirings 76 which extend and exist this insulating layer upper part, insulating layer 77 formed on the insulating layer as covered these wirings 76 of a plurality of, and a plurality of electrode pads 78 formed in the upper layer of insulating layer 77.

Each end side of a plurality of wirings 76 is connected to a plurality of electrode pads 73 electrically and respectively mechanically through the opening formed in the lower layer insulating layer, and the opening formed in passivation film 74.

A plurality of solder bumps 18 arranged on rewiring layer 75 are connected to each of a plurality of electrode pads 78 electrically and mechanically. As solder bump 18, the solder bump of Pb free composition, for example, the solder bump of Sn—Ag (silver)-Cu (copper) composition, is used.

Rewiring layer 75 is a layer for rearranging electrode pad 78 with an arraying pitch wide to electrode pad 73 of semiconductor chip layer 70. Electrode pad 78 of rewiring layer 75 is arranged with the same arraying pitch as the arraying pitch of the electrode pad of the mounting substrate on which CSP type semiconductor devices id are mounted.

As shown in FIG. 40, Ni films 11f are formed in the front surface of electrode pad 78. Solder bump 18 is joined to the Ni film 11f. The Ni film 11f has the same structure as Ni film 11b of the above-mentioned Example 1. That is, it has 2 layer structure by which first Ni layer 12a was formed on the surface of the electrode pad, and second Ni layer 12b was formed in the front surface of first Ni layer 12a. CSP type semiconductor device 1d intervenes solder bump 18 between electrode pad 78, and the electrode pad of a mounting substrate, and is mounted on a mounting substrate.

Thus, Ni film 11f on electrode pad 78 is made into 2 layer structure (from the electrode pad 7a side, Ni layer 12a/Ni layer 12b) which differs in the current density at the time of plating like the above-mentioned Example 1. Hereby, also in Example 4, the improvement in shock-resistant strength of a soldered joint is realizable, and the variation in the thickness of Ni film 11f can be reduced, and the thickness of Ni film 11f can be reduced further.

### Example 5

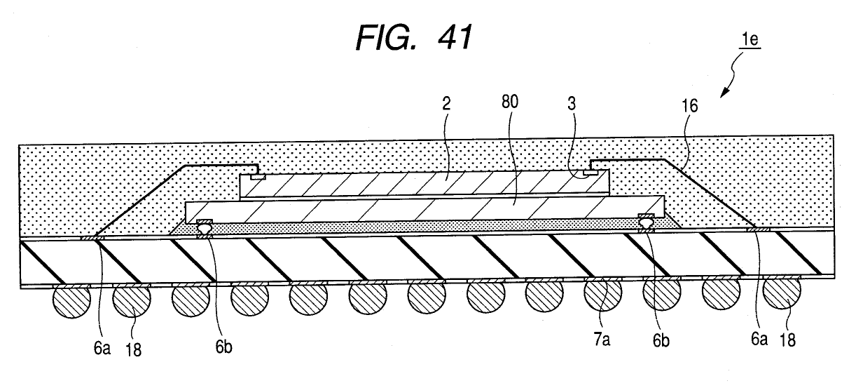

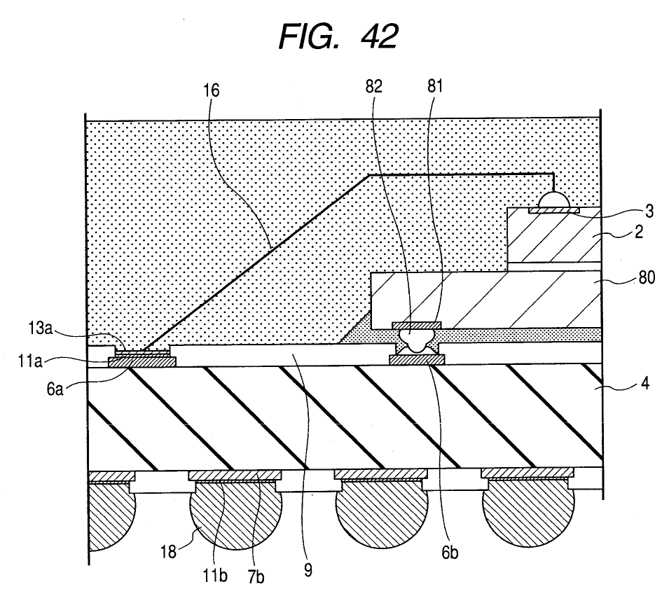

FIG. 41 is a schematic cross-sectional view showing the outline structure of the SiP type semiconductor device which is Example 5 of the present invention, and FIG. 42 is the schematic cross-sectional view which expanded a part of FIG. 41.

As shown in FIG. 41, semiconductor chip 80 is mounted in main surface 4x of wiring substrate 4 by a face-down-bonding system, and, as for SiP type semiconductor device 1e of Example 5, semiconductor chip 2 is mounted in the back surface of semiconductor chip 80 by the face-up-bonding system.

As shown in FIG. 42, a plurality of electrode pads 81 are arranged in the main surface of semiconductor chip 80, and stud bump 82 which includes Au is joined to each of these electrode pads 81 of a plurality of. Stud bump 82 is connected to electrode pad 6b of wiring substrate 4 electrically and mechanically via the solder layer called previous soldering. Connection between stud bump 82 and electrode pad 6b is made through the opening formed in protective film 9.

Microfabrication of the electrode pad 81 of semiconductor chip 80 is done with multi-functionalization or high integration. Microfabrication also of the stud bump 82 is done in connection with the microfabrication of electrode pad 81, and the height of stud bump 82 is low.

Since connection between stud bump 82 and electrode pad 6b will become difficult when the height of stud bump 82 becomes low, the thickness reduction of protective film 9 is required. When the thickness of protective film 9 becomes thin, it will become easy for Au film 13a and Ni film 11a to project from the front surface of protective film 9. Therefore, thickness reduction of protective film 9 can be aimed at by forming Ni film 11a by the same method as the above-mentioned Example 1. Even if the height of stud bump 82 becomes low with multi-functionalization or high integration, semiconductor chip 80 can be mounted in the main surface of wiring substrate 4 by a face-down-bonding system.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

What is claimed is:

1. A manufacturing method of a semiconductor device, comprising a step of:
forming a metallic film which uses first metal as a main ingredient by an electrolytic plating method over a surface of an electrode pad;
wherein the metallic film forming step includes a step which forms a first layer over a front surface of the electrode pad with a first current density, and a step which forms a second layer over a front surface of the first layer with a second current density higher than the first current density.

2. A manufacturing method of a semiconductor device according to claim 1, wherein
the first and the second layers are formed continuously.

3. A manufacturing method of a semiconductor device according to claim 1, wherein
the second layer has chlorine concentration lower than the first layer included in a layer.

4. A manufacturing method of a semiconductor device according to claim 1, wherein
the first metal is nickel.

5. A manufacturing method of a semiconductor device according to claim 1, comprising a step of:
forming Au film over the second layer after the metallic film forming step.

6. A manufacturing method of a semiconductor device according to claim 1, comprising a step of:
performing heat treatment and joining a solder material of Pb free composition to the second layer of the metallic film after the metallic film forming step.

7. A manufacturing method of a semiconductor device according to claim 1, comprising a step of:
performing heat treatment and forming a solder bump of Pb free composition joined to the second layer of the metallic film after the metallic film forming step.

8. A manufacturing method of a semiconductor device according to claim 1, wherein
the electrode pad includes a metallic film which uses Cu as a main ingredient.

9. A manufacturing method of a semiconductor device, comprising the steps of:
(a) preparing a wiring substrate which has a main surface and a back surface which are mutually located in an opposite side, and an electrode pad arranged at the back surface, and by which a metallic film which uses first metal as a main ingredient was formed over a front surface of the electrode pad;
(b) mounting a semiconductor chip over the main surface of the wiring substrate; and
(c) forming a resin sealing body which does resin seal of the semiconductor chip over the main surface of the wiring substrate;
wherein
the step (a) includes a step which forms the metallic film by an electrolytic plating method; and
the metallic film forming step includes a step which forms a first layer over a front surface of the electrode pad with a first current density, and a step which forms a second layer over a front surface of the first layer with a second current density higher than the first current density.

10. A manufacturing method of a semiconductor device according to claim 9, wherein
the first and the second layers are formed continuously.

11. A manufacturing method of a semiconductor device according to claim 9, wherein
the second layer has chlorine concentration lower than the first layer included in a layer.

12. A manufacturing method of a semiconductor device according to claim 9, wherein
the first metal is nickel.

13. A manufacturing method of a semiconductor device according to claim 9, wherein
the step (a) includes a step which forms Au film over a front surface of the second layer after the metallic film forming step.

14. A manufacturing method of a semiconductor device according to claim 9, wherein
after the step (c), lead free solder is melted and a bump joined to the first layer is formed.

15. A manufacturing method of a semiconductor device according to claim 9, wherein
the wiring substrate has a protective film which includes an insulating resin film at the main surface and the back surface;
the electrode pad is exposed from an opening formed in the protective film; and
the metallic film is formed over a front surface of the electrode pad in the opening.

16. A manufacturing method of a semiconductor device according to claim 9, wherein
the first and the second electrode pads include a metallic film which uses Cu as a main ingredient.

17. A manufacturing method of a semiconductor device, comprising the steps of:
(a) preparing a wiring substrate which has a main surface and a back surface which are mutually located in an opposite side, a first electrode pad arranged over the main surface, and a second electrode pad arranged over the back surface, and by which a metallic film which uses first metal as a main ingredient was formed over each front surface of the first and the second electrode pads;
(b) mounting a semiconductor chip over the main surface of the wiring substrate;
(c) electrically connecting an electrode pad of the semiconductor chip, and the first electrode pad of the wiring substrate by a bonding wire; and
(d) forming a resin sealing body which does resin seal of the semiconductor chip and the bonding wire over the main surface of the wiring substrate;
wherein
the step (a) includes a step which forms the metallic film by an electrolytic plating method; and
the metallic film forming step includes a step which forms a first layer over each front surface of the first and the second electrode pads with a first current density, and a step which forms a second layer over a front surface of the first layer of each with a second current density higher than the first current density.

18. A manufacturing method of a semiconductor device according to claim 17, wherein
the first and the second layers are formed continuously.

19. A manufacturing method of a semiconductor device according to claim 17, wherein
the second layer has chlorine concentration lower than the first layer included in a layer.

20. A manufacturing method of a semiconductor device according to claim 17, wherein
the first metal is nickel.

21. A manufacturing method of a semiconductor device according to claim 17, wherein
the step (a) includes a step which forms Au film over a front surface of the second layer after the metallic film forming step; and
the bonding wire is joined to the Au film.

22. A manufacturing method of a semiconductor device according to claim 17, comprising a step of:
melting lead free solder material and forming a bump joined to the metallic film over the second electrode pad after the step (d).

23. A manufacturing method of a semiconductor device according to claim 21, wherein
the wiring substrate has a first insulating resin film formed over the main surface of the wiring substrate, and a second insulating resin film formed over the back surface of the wiring substrate;
the first electrode pad is exposed from a first opening formed in the first insulating resin film;
the second electrode pad is exposed from a second opening formed in the second insulating resin film;
the metallic film and the Au film over the first electrode pad are formed over the first electrode pad in the first opening; and
the metallic film and the Au film over the second electrode pad are formed over the second electrode pad in the second opening.

24. A manufacturing method of a semiconductor device according to claim 17, wherein
the electrode pad includes a metallic film which uses Cu as a main ingredient.
